(19) United States
(12) Patent Application Publication
(10) Pub. No.: US 2026/0255911 A1
(43) Pub. Date: Aug. 27, 2026

(54) SUBSTRATE PROCESSING APPARATUS, PROCESSING LIQUID SUPPLY DEVICE, SUBSTRATE PROCESSING METHOD AND PROCESSING LIQUID SUPPLY METHOD

(71) Applicant: SCREEN HOLDINGS CO., LTD., Kyoto (JP)

(72) Inventors: Tetsuya WATANABE, Kyoto-shi (JP); Tomoaki AIHARA, Kyoto-shi (JP)

(21) Appl. No.: 19/536,514

(22) Filed: Feb. 11, 2026

(30) Foreign Application Priority Data
Feb. 26, 2025 (JP) 2025-028971

(51) Int. Cl. H10P 72/00

(52) U.S. Cl. CPC H10P 72/0458; H10P 72/0414

(57) ABSTRACT

A substrate processing apparatus includes a plurality of chambers, a processing liquid supply device and a controller. The processing liquid supply device includes a first temperature adjuster and a second temperature adjuster that adjust a temperature of a processing liquid supplied to the plurality of chambers, and a malfunction detector that detects a malfunction. In a case in which neither the first temperature adjuster nor the second temperature adjuster is malfunctioning, the controller sets a first number as the number of chambers to which the processing liquid can be simultaneously supplied from the processing liquid supply device. In a case in which only one of the first temperature adjuster and the second temperature adjuster is malfunctioning, a second number smaller than the first number is set as the number of chambers to which the processing liquid can be simultaneously supplied from the processing liquid supply device.

### BACKGROUND

### TECHNICAL FIELD

The present disclosure relates to a substrate processing apparatus and a substrate processing method for executing a process using a processing liquid on a plurality of substrates. Further, the present disclosure relates to a processing liquid supply device and a processing liquid supply method for supplying a processing liquid to a plurality of chambers.

### DESCRIPTION OF RELATED ART

A substrate processing apparatus is used to execute various processes on a substrate such as a semiconductor substrate, a substrate for an FPD (Flat Panel Display) that is used for a liquid crystal display device, an organic EL (Electro Luminescence) display device or the like, a substrate for an optical disc, a substrate for a magnetic disc, a substrate for a magneto-optical disc, a substrate for a photomask, a ceramic substrate or a substrate for a solar cell.

As one example of a substrate processing apparatus, a substrate processing apparatus that processes a substrate using a chemical liquid is described in JP 2021-52038 A. The substrate processing apparatus includes a plurality of processing units (chambers) and a chemical liquid supply device (processing liquid supply device). The processing liquid supply device supplies the chemical liquid to the plurality of chambers. In each chamber, a process of supplying the chemical liquid supplied from the processing liquid supply device to the substrate is executed.

### SUMMARY

In substrate processing using the chemical liquid, a film formed on the obverse surface of the substrate is etched, for example. In this case, a film etching rate changes depending on a temperature of the chemical liquid. Therefore, in order to reduce an occurrence of a substrate processing defect, the temperature of the chemical liquid supplied from the processing liquid supply device to the plurality of chambers is required to be appropriately adjusted according to a required etching amount.

As such, in the processing liquid supply device, a temperature adjustment device is provided in part of a pipe that supplies the chemical liquid to the plurality of chambers. However, when the temperature adjustment device of the processing liquid supply device malfunctions, the temperature of the chemical liquid cannot be adjusted, and thus defective products are mass-produced.

In order to prevent such a problem, in the processing liquid supply device, a thermal sensor for detecting a temperature of the chemical liquid supplied to the plurality of chambers is provided in addition to the temperature adjustment device. Further, the substrate processing apparatus is provided with a function (emergency stop function) of stopping the work of the processing liquid supply device and the work in all of the plurality of chambers in a case in which the temperature of the chemical liquid detected by the thermal sensor is out of a predetermined range.

However, in a case in which the entire substrate processing apparatus is stopped at an unintended point in time, a period of time required for recovery work of the substrate processing apparatus is likely to be long as compared with a case in which the time when the substrate processing apparatus is to be stopped is identified in advance. This is because it is difficult to perform, in advance, all of the preparations required for recovery work. Therefore, the sudden stop of the substrate processing apparatus significantly degrades production efficiency of substrate processing.

An object of the present disclosure is to provide a substrate processing apparatus, a processing liquid supply device, a substrate processing method and a processing liquid supply method that enable a reduction of possibility that work of a processing liquid supply device and work in a plurality of chambers are stopped at an unintended point in time.

A substrate processing apparatus according to one aspect of the present disclosure includes a plurality of chambers in which a plurality of substrates are respectively processed using a processing liquid, a processing liquid supply device that supplies the processing liquid to the plurality of chambers, and a controller that controls the plurality of chambers and the processing liquid supply device, wherein the processing liquid supply device includes a first temperature adjuster and a second temperature adjuster that adjust a temperature of the processing liquid to be supplied to the plurality of chambers, and a malfunction determiner that is configured to determine whether the first temperature adjuster is malfunctioning and determine whether the second temperature adjuster is malfunctioning, and the controller, in a case in which the malfunction determiner determines that neither the first temperature adjuster nor the second temperature adjuster is malfunctioning, sets a first number equal to or smaller than a count of the plurality of chambers as a count of chambers to which the processing liquid is allowed to be simultaneously supplied from the processing liquid supply device, and in a case in which the malfunction determiner determines that one of the first temperature adjuster and the second temperature adjuster is malfunctioning and determines that another one of the first temperature adjuster and the second temperature adjuster is not malfunctioning, sets a second number smaller than the first number as the count of chambers to which the processing liquid is allowed to be simultaneously supplied from the processing liquid supply device.

A processing liquid supply device according to another aspect of the present disclosure that supplies a processing liquid to a plurality of chambers, with the plurality of chambers respectively executing a process using the processing liquid on a plurality of substrates, includes a first temperature adjuster and a second temperature adjuster that adjust a temperature of the processing liquid to be supplied to the plurality of chambers, a malfunction determiner configured to determine whether the first temperature adjuster is malfunctioning and configured to determine whether the second temperature adjuster is malfunctioning, and a controller, in a case in which the malfunction determiner determines that neither the first temperature adjuster nor the second temperature adjuster is malfunctioning, outputs an instruction signal for setting a first number equal to or smaller than a count of the plurality of chambers as a count of chambers in which work is allowed to be simultaneously performed, and in a case in which the malfunction determiner determines that one of the first temperature adjuster and the second temperature adjuster is malfunctioning and determines that another one of the first temperature adjuster and the second temperature adjuster is not malfunctioning, outputs an instruction signal for setting a second number smaller than the first number as a count of chambers to which the processing liquid is allowed to be simultaneously supplied.

A substrate processing method according to yet another aspect of the present disclosure includes supplying a processing liquid to a plurality of chambers that respectively execute a process using the processing liquid on a plurality of substrates, and controlling the plurality of chambers, wherein the supplying a processing liquid to a plurality of chambers includes adjusting, using a first temperature adjuster and a second temperature adjuster, a temperature of the processing liquid to be supplied to the plurality of chambers, determining whether the first temperature adjuster is malfunctioning, and determining whether the second temperature adjuster is malfunctioning, and the controlling the plurality of chambers includes, in a case in which it is determined that neither the first temperature adjuster nor the second temperature adjuster is malfunctioning, setting a first number equal to or smaller than a count of the plurality of chambers as a count of chambers to which the processing liquid is allowed to be simultaneously supplied, and in a case in which it is determined that one of the first temperature adjuster and the second temperature adjuster is malfunctioning, and it is determined that another one of the first temperature adjuster and the second temperature adjuster is not malfunctioning, setting a second number smaller than the first number as a count of chambers to which the processing liquid is allowed to be simultaneously supplied.

A processing liquid supply method according to yet another aspect of the present disclosure of supplying a processing liquid to a plurality of chambers in which a plurality of substrates are respectively processed using a processing liquid, includes adjusting, using a first temperature adjuster and a second temperature adjuster, a temperature of the processing liquid to be supplied to the plurality of chambers, determining whether the first temperature adjuster is malfunctioning, determining whether the second temperature adjuster is malfunctioning, in a case in which it is determined that neither the first temperature adjuster nor the second temperature adjuster is malfunctioning, outputting an instruction signal for setting a first number equal to or smaller than a count of the plurality of chambers as a count of chambers in which work is allowed to be simultaneously performed, and in a case in which it is determined that one of the first temperature adjuster and the second temperature adjuster is malfunctioning, and it is determined that another one of the first temperature adjuster and the second temperature adjuster is not malfunctioning, outputting an instruction signal for setting a second number smaller than the first number as a count of chambers in which work is allowed to be simultaneously performed.

With the present disclosure, it is possible to reduce the possibility that the work of the processing liquid supply device and the work in the plurality of chambers are stopped at an unintended point in time.

Other features, elements, characteristics, and advantages of the present disclosure will become more apparent from the following description of preferred embodiments of the present disclosure with reference to the attached drawings.

### BRIEF DESCRIPTION OF THE DRAWING

FIG. 1 is a schematic configuration diagram of a substrate processing apparatus according to a first embodiment;

FIG. 2 is a block diagram showing the configuration of a control system of the substrate processing apparatus of FIG. 1;

FIG. 3 is a flowchart showing one example of a liquid supply process executed in the substrate processing apparatus 1 according to the first embodiment;

FIG. 4 is a schematic configuration diagram of a substrate processing apparatus according to a second embodiment;

FIG. 5 is a block diagram showing the configuration of a control system of the substrate processing apparatus of FIG. 4;

FIG. 6 is a flowchart showing one example of a liquid supply process executed in the substrate processing apparatus according to the second embodiment;

FIG. 7 is a schematic configuration diagram of a substrate processing apparatus according to a third embodiment;

FIG. 8 is a block diagram showing the configuration of a control system of the substrate processing apparatus of FIG. 7;

FIG. 9 is a flowchart showing one example of a liquid supply process executed in the substrate processing apparatus according to the third embodiment;

FIG. 10 is a schematic configuration diagram of a substrate processing apparatus according to a fourth embodiment;

FIG. 11 is a block diagram showing the configuration of a control system of the substrate processing apparatus of FIG. 10;

FIG. 12 is a flowchart showing one example of a liquid supply process executed in the substrate processing apparatus according to the fourth embodiment;

FIG. 13 is a schematic configuration diagram of a substrate processing apparatus according to a fifth embodiment;

FIG. 14 is a flowchart showing one example of a liquid supply process executed in the substrate processing apparatus according to the fifth embodiment;

FIG. 15 is a flowchart showing one example of a liquid supply process executed in the substrate processing apparatus according to the sixth embodiment;

FIG. 16 is a schematic configuration diagram of a substrate processing apparatus according to a seventh embodiment;

FIG. 17 is a block diagram showing the configuration of a control system of the substrate processing apparatus of FIG. 16;

FIG. 18 is a flowchart showing one example of a liquid supply process executed in the substrate processing apparatus according to the seventh embodiment;

FIG. 19 is a schematic configuration diagram of a substrate processing apparatus according to an eighth embodiment;

FIG. 20 is a block diagram showing the configuration of a control system of the substrate processing apparatus of FIG. 19; and

FIG. 21 is a flowchart showing one example of a liquid supply process executed in the substrate processing device according to the eighth embodiment.

### DETAILED DESCRIPTION

A substrate processing apparatus, a processing liquid supply device, a substrate processing method and a processing liquid supply method according to one embodiment of the present disclosure will be described below with reference to the drawings. In the following description, a substrate refers to a substrate for a Flat Panel Display (FPD) that is used for a liquid crystal display device, an organic Electro Luminescence (EL) display device or the like, a semiconductor substrate, a substrate for an optical disc, a substrate for a magnetic disc, a substrate for a magneto-optical disc, a substrate for a photomask, a ceramic substrate, a substrate for a solar cell or the like.

The below-mentioned substrate processing apparatus basically executes a process on a plurality of substrates using a processing liquid having a temperature in a

predetermined temperature range. In the following description, an ideal temperature of the processing liquid supplied to a substrate W is referred to as a target temperature, and the predetermined temperature range of the processing liquid which includes the target temperature and to which the temperature of the processing liquid is to be adjusted for a process for the substrate W is referred to as a processing allowable range.

### 1. First Embodiment

### <1> Configuration of Substrate Processing Apparatus

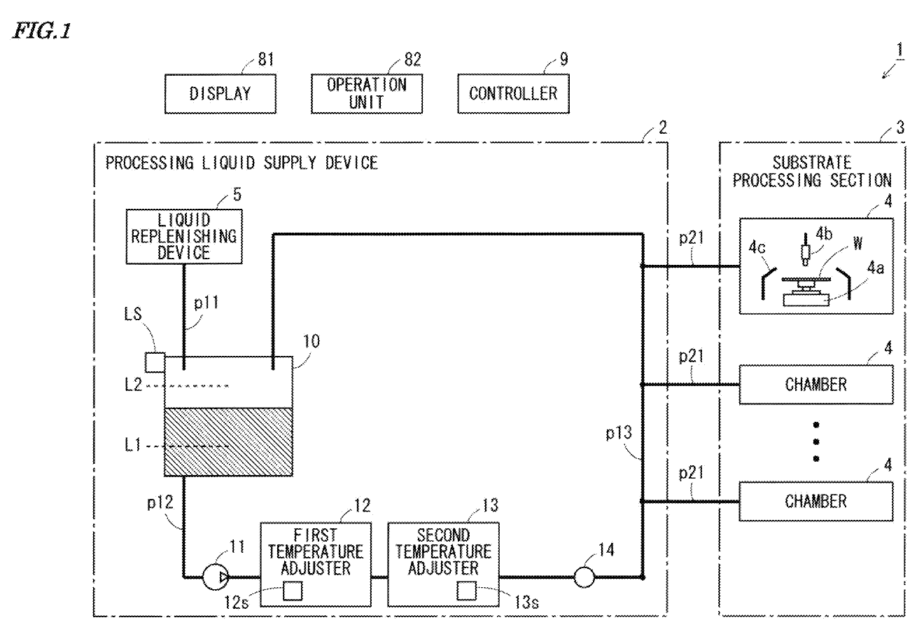

FIG. 1 is a schematic configuration diagram of a substrate processing apparatus according to a first embodiment. The substrate processing apparatus 1 includes a processing liquid supply device 2, a substrate processing section 3, a controller 9, a display 81 and an operation unit 82. In the present embodiment, a processing liquid used for processing the substrate W is a chemical liquid for etching a film such as a silicon oxide film, a silicon nitride film or a titanium nitride film, formed on the substrate W.

Examples of the chemical liquid include hydrofluoric acid (HF), buffered hydrofluoric acid (BHF), dilute hydrofluoric acid (DHF), a mixture of sulfuric acid and hydrogen peroxide (SPM), a mixture of ammonium water and hydrogen peroxide (SC1), a mixture of hydrochloric acid and hydrogen peroxide (SC2), diluted ammonium hydroxide (dNH₄OH), and tetramethylammonium hydroxide (TMAH). A target temperature and a processing allowable range of a processing liquid are determined according to the type of a chemical liquid to be used and the processing contents of the substrate W.

The processing liquid supply device 2 stores a certain amount of the processing liquid in a storage tank 10 described below, and supplies a temperature-adjusted processing liquid to the substrate processing section 3 while adjusting the temperature of the processing liquid in a processing allowable range. Details of configuration of the processing liquid supply device 2 will be described below.

The substrate processing section 3 includes a plurality (twelve, for example) of chambers 4. In each chamber 4, a spin chuck 4a, a nozzle 4b and a cup 4c are provided. The spin chuck 4a is configured to be capable of holding the substrate W to be processed. Further, the spin chuck 4a is driven by a driving device (not shown) (an electric motor, for example) to rotate while holding the substrate W. Thus, the substrate W held by the spin chuck 4a rotates.

The nozzle 4b discharges, to the substrate W held and rotated by the spin chuck 4a, part of the processing liquid supplied from the processing liquid supply device 2 to the substrate processing section 3. Thus, the obverse surface (the upper surface in the present example) of the substrate W is processed. The cup 4c is provided to surround the substrate W held by the spin chuck 4a, and receives the processing liquid splashing from the substrate W during a process for the substrate W. The processing liquid received by the cup 4c is sent to a liquid drainage facility provided outside of the substrate processing apparatus 1, for example. At least part of the processing liquid received by the cup 4c may be returned to the processing liquid supply device 2.

The controller 9 controls the work of each component of the processing liquid supply device 2 and the substrate processing section 3. Details of the controller 9 will be described below. The display 81 includes a liquid crystal display device or an organic EL display device, for example. An example of information displayed on the display 81 will be described below. The operation unit 82 includes a keyboard and a pointing device, for example, and is configured to be operable by a user. The user can input various information to the substrate processing apparatus 1 by operating the operation unit 82.

### <2> Configuration and Basic Work of Processing Liquid Supply Device 2

As shown in FIG. 1, the processing liquid supply device 2 includes a liquid replenishing device 5, the storage tank 10, a pump 11, a first temperature adjuster 12, a second temperature adjuster 13, a thermal sensor 14, a replenishing pipe p11, a supply pipe p12 and a circulation pipe p13.

The substrate processing apparatus 1 according to the present embodiment is provided in a factory, for example. In the factory, a supply source of a processing liquid used for processing the substrate W is provided as a utility facility used for the substrate processing apparatus 1.

The liquid replenishing device 5 includes fluid-related elements such as a pipe, a joint and a valve, and is connected to the supply source of a processing liquid (not shown). The liquid replenishing device 5 may include a pump as part of the fluid-related elements. The upstream end of the replenishing pipe p11 is further connected to the liquid replenishing device 5. The downstream end of the replenishing pipe p11 is arranged in the storage tank 10. The liquid replenishing device 5 is configured to be capable of supplying (replenishing) a processing liquid (a new processing liquid) of the supply source (not shown) to the storage tank 10 through the replenishing pipe p11.

The storage tank 10 is configured to be capable of storing a certain amount of the processing liquid. A liquid level sensor LS is attached to the storage tank 10. The liquid level sensor LS detects a liquid level (height of liquid level) of the processing liquid stored in the storage tank 10. Further, the liquid level sensor LS outputs a liquid level signal indicating the detected liquid level to the controller 9. As the liquid level sensor LS, a capacitance-type liquid level sensor, an optical-type liquid level sensor or an ultrasonic-type liquid level sensor can be used, for example.

The upstream end of the supply pipe p12 is connected to a bottom portion of the storage tank 10. In the supply pipe p12, the pump 11, the first temperature adjuster 12, the second temperature adjuster 13 and the thermal sensor 14 are provided so as to be arranged in this order from an upstream position to a downstream position.

The pump 11 sucks the processing liquid stored in the storage tank 10, and pumps the sucked processing liquid toward the downstream end of the supply pipe p12. The first temperature adjuster 12 is configured to be capable of adjusting the temperature of the processing liquid flowing through the supply pipe p12 to the target temperature. Therefore, in a case in which the target temperature is higher than the temperature in the factory or the temperature of the processing liquid with which the storage tank 10 is replenished, the first temperature adjuster 12 includes a heating device such as a heater. On the other hand, in a case in which the target temperature is lower than the temperature in the factory or the temperature of the processing liquid with which the storage tank 10 is replenished, the first temperature adjuster 12 includes a cooling device such as a cooling fan.

In addition to the above-mentioned example, the first temperature adjuster 12 may be configured to be capable of heating the processing liquid and cooling the processing liquid by including a Peltier element or a heat exchanger. The larger the adjustable temperature range of the processing liquid, the more improved a degree of freedom in regard to a process for the substrate W. For example, it is possible to adjust an etching amount over a wide range. The second temperature adjuster 13 has the same configuration as the first temperature adjuster 12, and works similarly to the first temperature adjuster 12.

The first temperature adjuster 12 and the second temperature adjuster 13 respectively include built-in malfunction detectors 12s, 13s that detect malfunctions of the temperature adjusters. Each of the malfunction detectors 12s, 13s detects a malfunction of a temperature adjuster in a case in which electrical conduction in the corresponding temperature adjuster is interrupted. Alternatively, each of the malfunction detectors 12s, 13s includes a thermal sensor, for example, and detects a malfunction of a temperature adjuster in a case in which the temperature of the corresponding temperature adjuster deviates from a temperature of the temperature adjuster that is normally working. Further, in a case in which the corresponding temperature adjuster is malfunctioning, each of the malfunction detectors 12s, 13s outputs a malfunction signal indicating a malfunction of the temperature adjuster to the controller 9.

The thermal sensor 14 detects a temperature of the processing liquid flowing downstream of the first temperature adjuster 12 and the second temperature adjuster 13 in the supply pipe p12. Further, the thermal sensor 14 outputs a temperature signal indicating the detected temperature of the processing liquid to the controller 9.

The upstream end of the circulation pipe p13 is connected to the downstream end of the supply pipe p12. The downstream end of the circulation pipe p13 is arranged in the storage tank 10. A plurality of chamber pipes p21 are connected to a plurality of portions of the circulation pipe p13. The plurality of chamber pipes p21 respectively correspond to the plurality of chambers 4 of the substrate processing section 3, and connect the plurality of portions of the circulation pipe p13 to the nozzles 4b of the plurality of chambers 4. A plurality of valves (not shown) are respectively provided in the plurality of chamber pipes p21. By switching of the open-close states of the plurality of valves, part of the processing liquid flowing through the circulation pipe p13 is selectively guided to one or more nozzles 4b of at least one of the plurality of chambers 4.

### <3> Processing Liquid Replenishing Function

In the processing liquid supply device 2 having the above-mentioned configuration, a large portion of the processing liquid flowing from the storage tank 10 to the supply pipe p12 returns to the storage tank 10 through the circulation pipe p13. That is, the large portion of the processing liquid stored in the storage tank 10 circulates through the storage tank 10, the supply pipe p12 and the circulation pipe p13. On the other hand, part of the processing liquid flowing from the storage tank 10 to the supply pipe p12 is supplied to the substrate processing section 3. Therefore, when no new processing liquid is supplied from the liquid replenishing device 5 to the storage tank 10, the liquid level of the processing liquid stored in the storage tank 10 is lowered each time the substrate processing is executed in the substrate processing section 3.

As such, the processing liquid supply device 2 according to the present embodiment is provided with a processing liquid replenishing function of suitably replenishing the storage tank 10 with the processing liquid. With the processing liquid replenishing function, the storage tank 10 is replenished with the processing liquid supplied from the liquid replenishing device 5 based on a liquid level of the processing liquid detected by the liquid level sensor LS and a plurality of liquid levels preset in the storage tank 10.

In the storage tank 10, a lower limit level L1 and a prescribed level L2 are set as the plurality of liquid levels. The lower limit level L1 is a liquid level corresponding to an amount of the processing liquid considered to be minimally required for supplying the processing liquid to the substrate processing section 3, and is used to determine whether to start replenishment with the processing liquid by the liquid replenishing device 5. On the other hand, the prescribed level L2 is a liquid level that is higher than the lower limit level L1, corresponds to an amount of the processing liquid considered to be sufficient for supplying the processing liquid to the substrate processing section 3, and corresponds to an amount of the processing liquid considered not to overflow from the storage tank 10. The prescribed level L2 is used to determine whether to stop the replenishment during replenishment with the processing liquid by the liquid replenishing device 5.

An example of replenishment of the storage tank 10 with a new processing liquid based on the lower limit level L1 and the prescribed level L2 will be described. First, suppose that the liquid level of the processing liquid stored in the storage tank 10 is higher than the lower limit level L1 and lower than the prescribed level L2. Suppose that no new processing liquid is not supplied from the liquid replenishing device 5 to the storage tank 10 in this state.

Next, suppose that the liquid level of the processing liquid in the storage tank 10 is lowered by execution of a process on a plurality of substrates in the substrate processing section 3, and the liquid level of the processing liquid reaches the lower limit level L1. In this case, at a point in time at which the liquid level of the processing liquid reaches the lower limit level L1, the supply of the new processing liquid from the liquid replenishing device 5 to the storage tank 10 is started.

When the supply of the new processing liquid is started, the liquid level of the processing liquid gradually rises. In a period during which the liquid level of the processing liquid is higher than the lower limit level L1 and lower than the prescribed level L2, the storage tank 10 is continuously replenished with the processing liquid supplied from the liquid replenishing device 5. Thereafter, suppose that the liquid level of the processing liquid reaches the prescribed level L2. At this time, the supply of the new processing liquid from the liquid replenishing device 5 to the storage tank 10 is stopped.

In this manner, with the processing liquid replenishing function of the substrate processing apparatus 1, the storage tank 10 is replenished with the processing liquid at an appropriate point in time. This prevents the processing liquid in the storage tank 10 from being depleted.

### <4> First Temperature Management Function for Processing Liquid

In each chamber 4 of the substrate processing section 3, when the temperature of the processing liquid supplied from the processing liquid supply device 2 is out of the processing allowable range, a desired process cannot be executed. A processing defect of the substrate W occurs. When a processing defect of the substrate W occurs continuously in each chamber 4, defective products are mass-produced. This wastes a large amount of the processing liquid and many substrates W.

As such, in the processing liquid supply device 2 according to the present embodiment, a first temperature management function of controlling the temperature of the processing liquid flowing downstream of the first temperature adjuster 12 and the second temperature adjuster 13 is provided. In the first temperature management function, the entire substrate processing apparatus 1 is allowed to work or restricted from working based on a temperature of the processing liquid detected by the thermal sensor 14.

Specifically, the thermal sensor 14 detects a temperature of the processing liquid flowing through the supply pipe p12 and outputs a temperature signal, each time a very short period of time elapses. Based on a temperature signal output from the thermal sensor 14, it is determined whether a current temperature of the processing liquid is in the processing allowable range. In a case in which a current temperature of the processing liquid is in the processing allowable range, the entire substrate processing apparatus 1 is allowed to work. On the other hand, in a case in which a current temperature of the processing liquid is out of the processing allowable range, the entire substrate processing apparatus 1 is restricted from working. That is, the entire substrate processing apparatus 1 is stopped.

In this manner, with the first temperature management function of the processing liquid of the substrate processing apparatus 1, the processing liquid having a temperature out of the processing allowable range is not supplied to the substrate processing section 3. This suppresses an occurrence of a processing defect caused by a temperature of the processing liquid in each chamber 4. Therefore, the substrates W are prevented from being continuously inappropriately processed. Further, wasteful consumption of the processing liquid and the substrates W is suppressed.

### <5> Second Temperature Management Function for Processing Liquid

In the processing liquid supply device 2, the temperature of the processing liquid circulating through the storage tank 10, the supply pipe p12 and the circulation pipe p13 is adjusted by the first temperature adjuster 12 and the second temperature adjuster 13. Therefore, if the first temperature adjuster 12 and the second temperature adjuster 13 are malfunctioning, the temperature of the processing liquid flowing through the supply pipe p12 is not adjusted. Therefore, the temperature of the processing liquid is highly likely to significantly deviate from the processing allowable range.

As such, in the processing liquid supply device 2 according to the present embodiment, a second temperature management function is provided in addition to the above-mentioned first temperature management function. With the second temperature management function, the work of the entire substrate processing apparatus 1 is allowed or restricted based on malfunction signals output from the malfunction detectors 12s, 13s of the first temperature adjuster 12 and the second temperature adjuster 13.

Specifically, whether malfunction signals are output from both of the two malfunction detectors 12s, 13s is determined. In a case in which a malfunction signal is not output from either of the two malfunction detectors 12s, 13s, or in a case in which a malfunction signal is output from only one of the two malfunction detectors 12s, 13s, the work of the entire substrate processing apparatus 1 is allowed. In contrast, in a case in which malfunction signals are output from both of the two malfunction detectors 12s, 13s, the work of the entire substrate processing apparatus 1 is restricted. That is, the entire substrate processing apparatus 1 is stopped.

In this manner, with the second temperature management function for the processing liquid of the substrate processing apparatus 1, the processing liquid having a temperature out of the processing allowable range is unlikely to be supplied to the substrate processing section 3. This suppresses an occurrence of a processing defect caused by a temperature of the processing liquid in each chamber 4. Therefore, the substrates W are prevented from being continuously inappropriately processed. Further, wasteful consumption of the processing liquid and the substrates W is suppressed.

### <6> Exclusive Processing Function of Substrate Processing Apparatus 1

In the processing liquid supply device 2 according to the present embodiment, the flow rate of the processing liquid circulating through the storage tank 10, the supply pipe p12 and the circulation pipe p13 is maintained constant.

In the substrate processing apparatus 1 of FIG. 1, the first temperature adjuster 12 and the second temperature adjuster 13 are arranged in series on the one supply pipe p12. Thus, even in a case in which one of the first temperature adjuster 12 and the second temperature adjuster 13 is malfunctioning, when the other one of the first temperature adjuster 12 and the second temperature adjuster 13 is working normally, adjustment of the temperature of the processing liquid is continued. However, when one temperature adjuster is malfunctioning, an amount of energy that can be applied to the processing liquid flowing through the supply pipe p12 per unit time changes as compared with a case in which neither of the two temperature adjusters is malfunctioning.

Therefore, when the storage tank 10 is replenished with a new processing liquid, it may be difficult to set the temperature of the processing liquid flowing downstream of the second temperature adjuster 13 in the processing allowable range depending on the temperature of the new processing liquid. When the temperature of the processing liquid flowing downstream of the second temperature adjuster 13 is out of the processing allowable range, the entire substrate processing apparatus 1 is stopped by the first temperature management function.

As described in summary, the sudden stop of work of the substrate processing apparatus 1 significantly degrades the production efficiency of a substrate process. As such, in the substrate processing apparatus 1 according to the present embodiment, an exclusive processing function of reducing the flow rate of the processing liquid supplied to the substrate processing section 3 in a case in which only one of the first temperature adjuster 12 and the second temperature adjuster 13 is malfunctioning is provided.

Here, suppose that, in the substrate processing apparatus 1, the number (count) of chambers 4 to which the processing liquid can be simultaneously supplied from the processing liquid supply device 2 is set as the number (count) of chambers in which a process is executable. The number of chambers in which a process is executable may be the number of chambers 4 in which work can be simultaneously performed (processes can be executed in parallel) in the substrate processing section 3.

With the exclusive processing function of the present example, whether malfunction signals are output from both of the two malfunction detectors 12s, 13s is determined. In a case in which a malfunction signal is not output from either of the two malfunction detectors 12s, 13s, a first number equal to or smaller than the number (count) of the plurality of chambers 4 of the substrate processing section 3 is set as the number of chambers in which a process is executable. For example, in a case in which the number of the plurality of chambers 4 of the substrate processing section 3 is twelve, the first number may be “12” or “11.” In this case, in the substrate processing section 3, it is possible to process the plurality of substrates W with high efficiency using a temperature-adjusted processing liquid.

On the other hand, in a case in which a malfunction signal is output from only one of the two malfunction detectors 12s, 13s, a second number smaller than the first number is set as the number of chambers in which a process is executable. For example, in a case in which the first number is “12,” the second number may be “6” or “5.” This reduces the supply flow rate of the processing liquid to the substrate processing section 3 as compared with a case in which neither of the two temperature adjusters (12, 13) is malfunctioning. That is, a reduction amount of the processing liquid in the storage tank 10 per unit time is reduced. Therefore, even in a case in which one of the two temperature adjusters (12, 13) is malfunctioning, it is possible to maintain the work state of the substrate processing section 3 without causing a processing defect of the substrate W at least for a certain period of time. As a result, it reduces the possibility that the work of the processing liquid supply device 2 and the work in all of the plurality of chambers 4 are stopped at an unintended point in time.

The first number and the second number are determined in advance according to the flow rate of the processing liquid circulating through the processing liquid supply device 2, the capacity of the storage tank 10, and the like. That is, the first number and the second number are determined according to the processing liquid supply capacity of the processing liquid supply device 2. Further, the second number is preferably a value equal to or smaller than 3/4 of the first number, and more preferably equal to or smaller than 1/2 of the first number.

### <7> Control System of Substrate Processing Apparatus

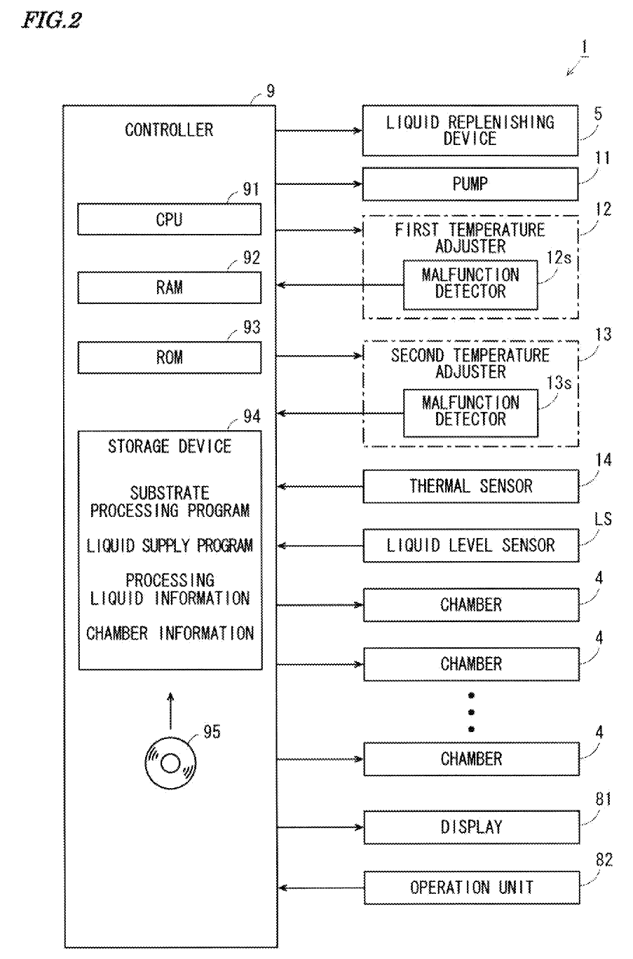

A control system of the substrate processing apparatus 1 will be described together with the configuration of the controller 9 of FIG. 1. FIG. 2 is a block diagram showing the configuration of the control system of the substrate processing apparatus 1 of FIG. 1. As shown in FIG. 2, the controller 9 includes a Central Processing Unit (CPU) 91, a Random Access Memory (RAM) 92, a Read Only Memory (ROM) 93 and a storage device 94.

The RAM 92 is used as a work area for the CPU 91. A system program is stored in the ROM 93. The storage device 94 includes a storage medium such as a hard disc or a semiconductor memory, and stores a substrate processing program for executing a process on a substrate in the substrate processing section 3 and a liquid supply program for supplying the processing liquid to the plurality of chambers 4 in the processing liquid supply device 2.

Further, the storage device 94 stores processing liquid information relating to the processing liquid and chamber information relating to a chamber in which work is to be performed among the plurality of chambers 4. The processing liquid information according to the present embodiment includes the target temperature, the processing allowable range, the lower limit level L1 and the prescribed level L2, described above. The chamber information according to the present embodiment includes the number of chambers in which a process is executable, described above.

The substrate processing program and the liquid supply program may be provided in the state of being stored in a recording media such as a CD-ROM 95 and installed in the ROM 93 or the storage device 94. Alternatively, the substrate processing program and the liquid supply program may be distributed from a server outside of the substrate processing apparatus 1 through a communication network and installed in the ROM 93 or the storage device 94.

When the CPU 91 executes the liquid supply program, a necessary amount of the processing liquid is supplied from the processing liquid supply device 2 to the substrate processing section 3. Further, when the CPU 91 executes the substrate processing program, the work of each component of the substrate processing section 3 is controlled, and a process is executed on a substrate using the processing liquid in each of the plurality of chambers 4.

The work of the controller 9 when the substrate processing program and the liquid supply program are executed will be described. The controller 9 receives a liquid level signal output from the liquid level sensor LS. Thus, the controller 9 controls the liquid replenishing device 5 based on a detection result of the liquid level sensor LS and the processing liquid information.

Specifically, in a case in which the liquid level of the processing liquid in the storage tank 10 is lowered to the lower limit level L1, the controller 9 causes the liquid replenishing device 5 to replenish the storage tank 10 with the processing liquid. Further, in a case in which the liquid level of the processing liquid in the storage tank 10 rises to the prescribed level L2, the controller 9 causes the liquid replenishing device 5 to stop replenishing the storage tank 10 with the processing liquid. Thus, in the storage tank 10, each time the liquid level of the processing liquid is lowered to the lower limit level L1, the liquid level of the processing liquid rises to the prescribed level L2.

Further, the controller 9 controls the work state of the pump 11. In the present embodiment, the controller 9 controls the pump 11 such that the pump 11 works at a constant output.

The controller 9 receives a temperature signal output from the thermal sensor 14.

Thus, the controller 9 controls the first temperature adjuster 12 and the second temperature adjuster 13 based on a detection result of the thermal sensor 14 and the processing liquid information. Specifically, the controller 9 performs feedback control of the first temperature adjuster 12 and the second temperature adjuster 13 such that the detection result of the thermal sensor 14 is brought close to the target temperature.

The controller 9 receives a malfunction signal output from the malfunction detector 12s when the first temperature adjuster 12 is malfunctioning. Thus, the controller 9 determines that the first temperature adjuster 12 is malfunctioning in a case in which the controller 9 receives a malfunction signal from the malfunction detector 12s, and determines that the first temperature adjuster 12 is not malfunctioning when the controller 9 does not receive a malfunction signal from the malfunction detector 12s.

The controller 9 receives a malfunction signal output from the malfunction detector 13s when the second temperature adjuster 13 is malfunctioning. Thus, the controller 9 determines that the second temperature adjuster 13 is malfunctioning in a case in which the controller 9 receives a malfunction signal from the malfunction detector 13s, and determines that the second temperature adjuster 13 is not malfunctioning when the controller 9 does not receive a malfunction signal from the malfunction detector 13s.

Further, the controller 9 sets the number of chambers in which a process is executable based on a determination result of whether each of the first temperature adjuster 12 and the second temperature adjuster 13 is malfunctioning. Further, among the plurality of chambers 4, the controller 9 controls the work in chambers 4 the number of which is the number of chambers in which a process is executable. Thus, the substrate W is processed in the chambers 4 the number of which is the number of chambers in which a process is executable. Alternatively, the controller 9 stops the work in the plurality of chambers 4 in a case in which both of the first temperature adjuster 12 and the second temperature adjuster 13 are malfunctioning.

Further, the controller 9 controls the work in the plurality of chambers 4 based on a detection result of the thermal sensor 14 and the processing liquid information. Thus, in a case in which the temperature of the processing liquid detected by the thermal sensor 14 is out of the processing allowable range, the work in the plurality of chambers 4 is stopped.

Further, with the power of the substrate processing apparatus 1 turned on , the controller 9 causes the display 81 to display a character string or an image indicating a determination result of whether each of the first temperature adjuster 12 and the second temperature adjuster 13 is malfunctioning. Thus, the user can easily identify whether each of the first temperature adjuster 12 and the second temperature adjuster 13 is malfunctioning by viewing the display 81.

Further, in a case in which the temperature of the processing liquid detected by the thermal sensor 14 is out of the processing allowable range, the controller 9 outputs a warning through the display 81. Further, the controller 9 outputs a warning through the display 81 in a case in which both of the first temperature adjuster 12 and the second temperature adjuster 13 are malfunctioning.

The user can input at least part of the processing liquid information and the chamber information, described above, by operating the operation unit 82. When various information pieces are input, the controller 9 stores the input information pieces in the storage device 94.

### <8> Liquid Supply Process

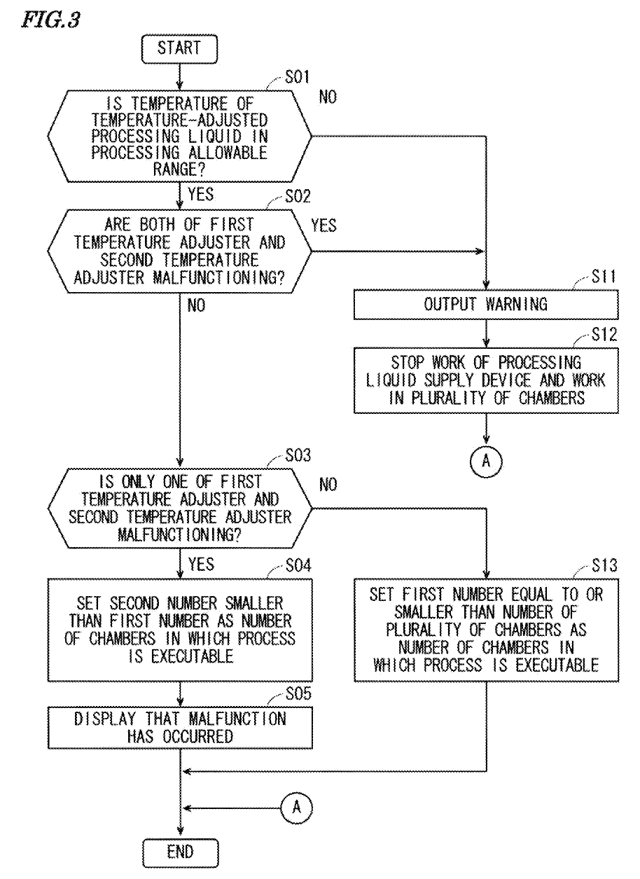

FIG. 3 is a flowchart showing one example of a liquid supply process executed in the substrate processing apparatus 1 according to the first embodiment. The below-mentioned liquid supply process is executed in a case in which the liquid supply program stored in the storage device 94 is executed by the CPU 91 of the controller 9 while the CPU 91 utilizes the RAM 92 as a work area.

The liquid supply process is started when the power of the substrate processing apparatus 1 is turned on, and is repeatedly executed each time a predetermined period of time elapses. When the liquid supply process is started, the CPU 91 determines whether the temperature of a temperature-adjusted processing liquid is in the processing allowable range based on a temperature signal output from the thermal sensor 14 (step S01).

In a case in which the temperature of the temperature-adjusted processing liquid is in the processing allowable range, the CPU 91 determines whether both of the first temperature adjuster 12 and the second temperature adjuster 13 are malfunctioning based on whether malfunction signals are output from the malfunction detectors 12s, 13s (step S02). In other words, the CPU 91 determines whether at least one of the first temperature adjuster 12 and the second temperature adjuster 13 is not malfunctioning. Specifically, in a case in which a malfunction signal is not output from the malfunction detector 12s, the CPU 91 determines that the first temperature adjuster 12 is not malfunctioning. In a case in which a malfunction signal is output from the malfunction detector 12s, the CPU 91 determines that the first temperature adjuster 12 is malfunctioning. Further, in a case in which a malfunction signal is not output from the malfunction detector 13s, the CPU 91 determines that the second temperature adjuster 13 is not malfunctioning. In a case in which a malfunction signal is output from the malfunction detector 13s, the CPU 91 determines that the second temperature adjuster 13 is malfunctioning.

In a case in which at least one of the first temperature adjuster 12 and the second temperature adjuster 13 is not malfunctioning, the CPU 91 determines whether only one of the first temperature adjuster 12 and the second temperature adjuster 13 is malfunctioning (step S03).

In a case in which neither the first temperature adjuster 12 nor the second temperature adjuster is malfunctioning, the CPU 91 sets a first number equal to or smaller than the number of the plurality of chambers 4 of the substrate processing section 3 as the number of chambers in which a process is executable (step S13). That is, the CPU 91 stores the first number equal to or smaller than the number of the plurality of chambers 4 of the substrate processing section 3 in the storage device 94 as the number of chambers 4 in which work can be simultaneously performed in the substrate processing section 3. Thereafter, the CPU 91 ends the liquid supply process.

In the step S03, in a case in which only one of the first temperature adjuster 12 and the second temperature adjuster 13 is malfunctioning, the CPU 91 sets a second number smaller than the first number as the number of chambers in which a process is executable (step S04). That is, the CPU 91 stores the second number smaller than the first number in the storage device 94 as the number of chambers 4 in which work can be simultaneously performed in the substrate processing section 3.

Next, the CPU 91 causes the display 81 to display that one of the first temperature adjuster 12 and the second temperature adjuster 13 is malfunctioning (step S05), and ends the liquid supply process.

The CPU 91 executes the substrate processing program in parallel with the above-mentioned liquid supply process. Thus, the plurality of substrates W are processed using the processing liquid in the chambers 4 the number of which is set in either the step S04 or the step S13 of the liquid supply process.

Description will be made in regard to a case in which the temperature of the temperature-adjusted processing liquid is not in the processing allowable range in the step S01, and a case in which both of the first temperature adjuster 12 and the second temperature adjuster 13 are malfunctioning in the step S02. In these cases, the CPU 91 outputs a warning (step S11). Specifically, the CPU 91 causes the display 81 to display a character string or an image indicating that the temperature of the temperature-adjusted processing liquid is not in the processing allowable range. Alternatively, the CPU 91 causes the display 81 to display a character string or an image indicating that both of the first temperature adjuster 12 and the second temperature adjuster 13 are malfunctioning. Further, the CPU 91 causes the display 81 to display a character string or an image indicating that urgent maintenance is required.

Thereafter, the CPU 91 stops the work of the entire processing liquid supply device 2 and the substrate processing section 3 (step S12), and ends the liquid supply process.

In the above-mentioned liquid supply process, the process of the steps S01, S11 and S12 correspond to the first temperature management function. Further, in the liquid supply process, the process of the steps S02, S11 and S12 correspond to the second temperature management function. Further, in the liquid supply process, the process of the steps S03, S04 and S13 correspond to the exclusive processing function. Note that the processing liquid replenishing function of the processing liquid supply device 2 continuously works based on the processing liquid information (the set lower limit level L1 and the set prescribed level L2) regardless of the above-mentioned liquid supply process.

### <9> Effects

In the above-mentioned substrate processing apparatus 1, whether the first temperature adjuster 12 and the second temperature adjuster 13 are malfunctioning is determined. In a case in which neither the first temperature adjuster 12 nor the second temperature adjuster 13 is malfunctioning, the first number is set as the number of chambers in which a process is executable. Therefore, by appropriately defining the first number, it is possible to process the plurality of substrates W with high efficiency using the temperature-adjusted processing liquid.

In a case in which one of the first temperature adjuster 12 and the second temperature adjuster 13 is malfunctioning and the other one of the first temperature adjuster 12 and the second temperature adjuster 13 is not malfunctioning, the second number smaller than the first number is set as the number of chambers in which a process is executable. Thus, the flow rate of the processing liquid supplied to the substrate processing section 3 is reduced as compared with a case in which the first number is set. Therefore, it is possible to maintain the work state of the substrate processing section 3 without causing a processing defect of the substrate W at least for a certain period of time. As a result, it is possible to reduce the possibility that the work of the processing liquid supply device 2 and the work in all of the plurality of chambers 4 are stopped due to the first temperature management function at an unintended point in time.

### 2. Second Embodiment

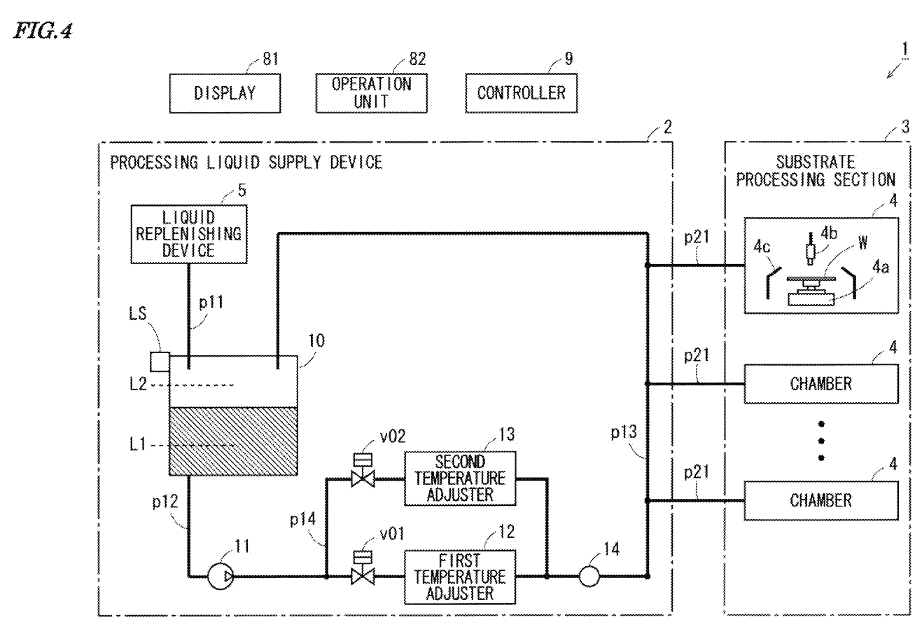

The differences of a substrate processing apparatus 1 according to a second embodiment from the substrate processing apparatus 1 according to the first embodiment will be described. FIG. 4 is a schematic configuration diagram of the substrate processing apparatus according to the second embodiment. As shown in FIG. 4, in a processing liquid supply device 2 according to the present embodiment, a bypass pipe p14 is provided in a supply pipe p12. Specifically, the bypass pipe p14 is connected to the supply pipe p12 so as to bypass one portion of the supply pipe p12 and connect two portions of the supply pipe p12 to each other.

In the one portion of the supply pipe p12, a valve v01 and a first temperature adjuster 12 are provided in this order from an upstream position to a downstream position. In the bypass pipe p14, a valve v02 and a second temperature adjuster 13 are provided in this order from an upstream position to a downstream position. Thus, the first temperature adjuster 12 and the second temperature adjuster 13 are arranged in parallel on the supply pipe p12 and the bypass pipe p14.

The valve v01 is a ball valve, for example, and allows a flow of a processing liquid through the one portion of the supply pipe p12 when the valve v01 is in an open state, and blocks a flow of the processing liquid through the one portion of the supply pipe p12 when the valve v01 is in a close state. The valve v02 is a ball valve, for example, and allows a flow of the processing liquid through the bypass pipe p14 when the valve v02 is in an open state, and blocks a flow of the processing liquid through the bypass pipe p14 when the valve v02 is in a close state.

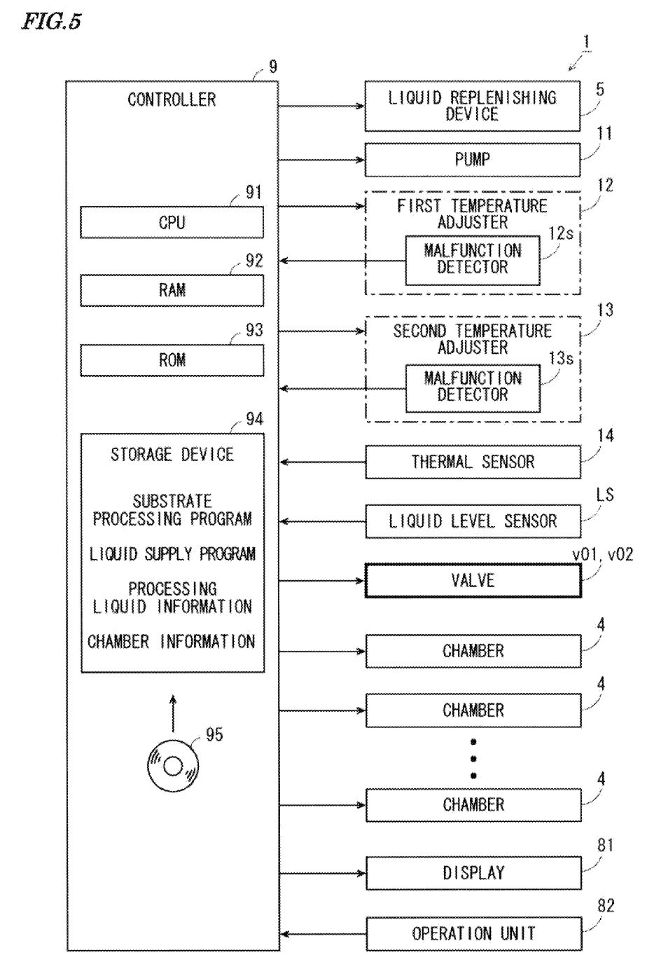

FIG. 5 is a block diagram showing the configuration of a control system of the substrate processing apparatus 1 of FIG. 4. In FIG. 5, the difference from the control system of FIG. 2 according to the first embodiment is indicated by the thick solid lines. As shown in FIG. 5, the controller 9 controls the valves v01, v02 in addition to the plurality of constituent elements of the substrate processing apparatus 1 according to the first embodiment.

Specifically, the controller 9 puts the valve v01 in the open state in a case in which the first temperature adjuster 12 is not malfunctioning, and puts the valve v01 in the close state in a case in which the first temperature adjuster 12 is malfunctioning. Thus, in a case in which the first temperature adjuster 12 is not malfunctioning, the processing liquid flows through the one portion of the supply pipe p12, and the temperature of the processing liquid is adjusted by the first temperature adjuster 12. On the other hand, when the first temperature adjuster 12 is malfunctioning, a flow of the processing liquid through the one portion of the supply pipe p12 is blocked.

Further, the controller 9 puts the valve v02 in the open state in a case in which the second temperature adjuster 13 is not malfunctioning, and puts the valve v02 in the close state in a case in which the second temperature adjuster 13 is malfunctioning. Thus, in a case in which the second temperature adjuster 13 is not malfunctioning, the processing liquid flows through the bypass pipe p14, and the temperature of the processing liquid is adjusted by the second temperature adjuster 13. On the other hand, when the second temperature adjuster 13 is malfunctioning, a flow of the processing liquid through the bypass pipe p14 is blocked.

As a result, the processing liquid the temperature of which is not adjusted is not supplied to a plurality of chambers 4 of a substrate processing section 3. Thus reduces the possibility that the temperature of the processing liquid supplied to the substrate processing section 3 becomes unstable.

In a portion of the flow path of the processing liquid, with the portion being formed of a pipe, it is possible to relatively easily suppress an increase in pressure loss by suitably selecting the specification of the pipe. On the other hand, in a portion of the flow path of the processing liquid, with the portion being formed of the valves v01, v02, the first temperature adjuster 12 and the second temperature adjuster 13, described above, selectable specifications (sizes and the like) of each of the constituent elements (v01, v02, 12, 13) are often restricted to some extent. Therefore, it may be difficult to suppress a pressure loss generated in each of the constituent elements (v01, v02, 12, 13) by selecting the specifications of the constituent elements. As such, in the processing liquid supply device 2 according to the present embodiment, the valves v01, v02, the first temperature adjuster 12 and the second temperature adjuster 13 are arranged in parallel as described above.

With the above-mentioned configuration, in a case in which neither the first temperature adjuster 12 nor the second temperature adjuster 13 is malfunctioning, the valves v01, v02 are brought into the open state. Thus, during normal running of the first temperature adjuster 12 and the second temperature adjuster 13, as compared with a case in which the first temperature adjuster 12 and the second temperature adjuster 13 are arranged in series, it can reduce a pressure loss generated in the valves v01, v02, the first temperature adjuster 12 and the second temperature adjuster 13. In other words, during normal running of the first temperature adjuster 12 and the second temperature adjuster 13, it is possible to reduce a pressure loss generated in each of the constituent elements (v01, v02, 12, 13) regardless of the specifications of the valves v01, v02, the first temperature adjuster 12 and the second temperature adjuster 13.

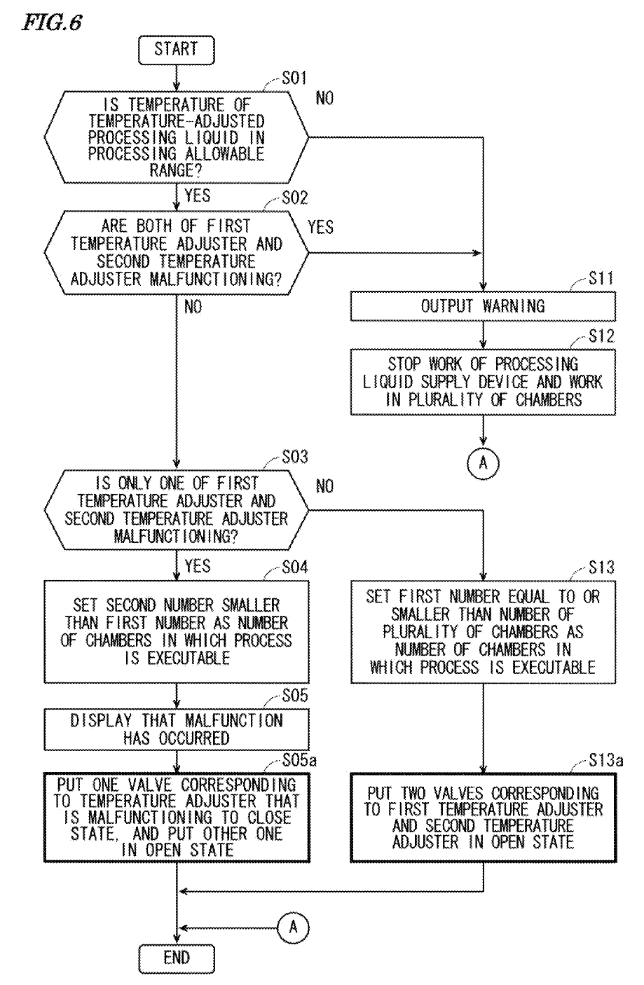

FIG. 6 is a flowchart showing one example of a liquid supply process executed in the substrate processing apparatus 1 according to the second embodiment. In FIG. 6, the differences from the liquid supply process of FIG. 3 according to the first embodiment are indicated by the thick solid lines.

In the liquid supply process according to the present embodiment, a CPU 91 controls the two valves v01, v02 of FIG. 4 after sequentially executing the same process as the process of the steps S01, S02, S03, S04 and S05 of FIG. 3. Specifically, the CPU 91 puts one valve corresponding to a temperature adjuster that is malfunctioning in the close state, and puts another valve corresponding to a temperature adjuster that is not malfunctioning in the open state (step S05a), and ends the liquid supply process.

Thus, in a case in which the first temperature adjuster 12 is malfunctioning and the second temperature adjuster 13 is not malfunctioning, the one valve v01 is put in the close state, and the other valve v02 is put in the open state. Further, in a case in which the first temperature adjuster 12 is not malfunctioning and the second temperature adjuster 13 is malfunctioning, the one valve v01 is put in the open state, and the other valve v02 is put in the close state.

Further, in the liquid supply process according to the present embodiment, the CPU 91 controls the two valves v01, v02 of FIG. 4 after sequentially executing the same process as the process of the steps S01, S02, S03 and S13 of FIG. 3. Specifically, the CPU 91 puts the two valves v01, v02 corresponding to the first temperature adjuster 12 and the second temperature adjuster 13 in the open state (step S13a), and ends the liquid supply process.

In the process of the above-mentioned steps S05a and S13a, the processing liquid the temperature of which is not adjusted by one of the first temperature adjuster 12 and the second temperature adjuster 13 is not supplied to the substrate processing section 3. This reduces the possibility that the temperature of the processing liquid supplied from the processing liquid supply device 2 to the substrate processing section 3 becomes unstable.

### 3. Third Embodiment

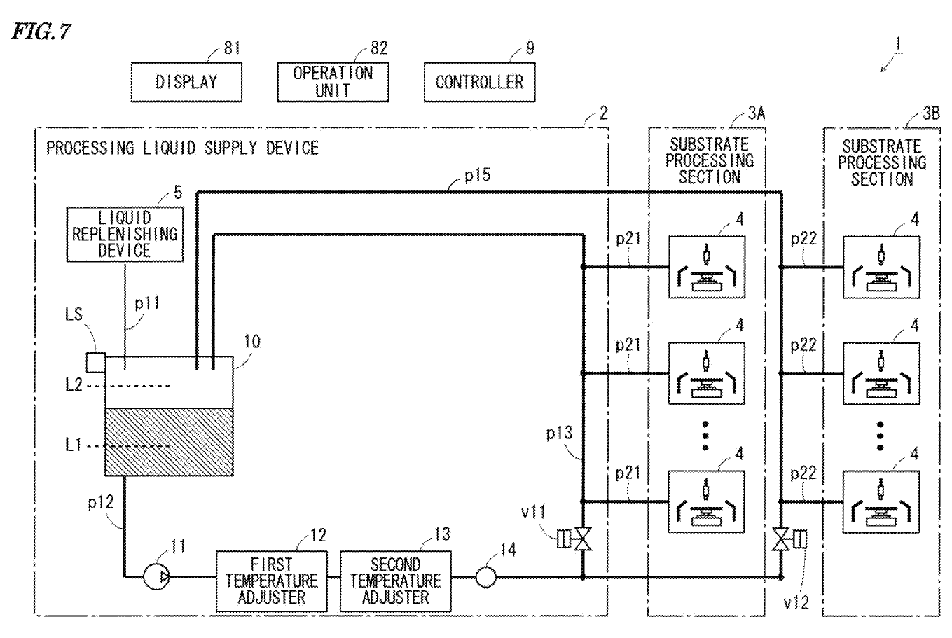

The differences of a substrate processing apparatus 1 according to a third embodiment from the substrate processing apparatus 1 according to the first embodiment will be described. FIG. 7 is a schematic configuration diagram of the substrate processing apparatus according to the third embodiment. As shown in FIG. 7, the substrate processing apparatus 1 according to the present embodiment includes two substrate processing sections 3A, 3B instead of the one substrate processing section of FIG. 1.

Each of the two substrate processing sections 3A, 3B has the same configuration as that of the substrate processing section 3 of FIG. 1. In each of the two substrate processing sections 3A, 3B, a plurality of chambers 4 are stacked. The structure in which the plurality of chambers are stacked is also referred to as a tower. Circulation pipes p13, p15 for supplying a processing liquid to each of the substrate processing sections 3A, 3B are connected to a supply pipe p12 of a processing liquid supply device 2. The circulation pipe p13 corresponds to the substrate processing section 3A, and the circulation pipe p15 corresponds to the substrate processing section 3B.

Specifically, the upstream end of the one circulation pipe p13 is connected between a thermal sensor 14 and the downstream end of the supply pipe p12, in a supply pipe p12. The downstream end of the circulation pipe p13 is arranged in a storage tank 10. Similarly to the example of FIG. 1, a plurality of chamber pipes p21 are connected to a plurality of portions of the circulation pipe p13. The plurality of chamber pipes p21 of the present example respectively correspond to the plurality of chambers 4 of the substrate processing section 3A.

A valve p11 is provided between the upstream end of the circulation pipe p13 and connecting portions of the plurality of chamber pipes p21, in the circulation pipe p13. The valve v11 is a ball valve, for example, and allows a flow of the processing liquid through the circulation pipe p13 when being in an open state, and blocks a flow of the processing liquid through the circulation pipe p13 when being in a close state.

The upstream end of the other circulation pipe p15 is connected to the downstream end of the supply pipe p12. The downstream end of the circulation pipe p15 is arranged in the storage tank 10. A plurality of chamber pipes p22 are connected to a plurality of portions of the circulation pipe p15. The plurality of chamber pipes p22 of the present example respectively correspond to the plurality of chambers 4 of the substrate processing section 3B.

A valve v12 is provided between the upstream end of the circulation pipe p15 and connecting portions of the plurality of chamber pipes p22, in the circulation pipe p15. The valve v12 is a ball valve, for example, and allows a flow of the processing liquid through the circulation pipe p15 when being in an open state, and blocks a flow of the processing liquid through the circulation pipe p15 when being in a close state.

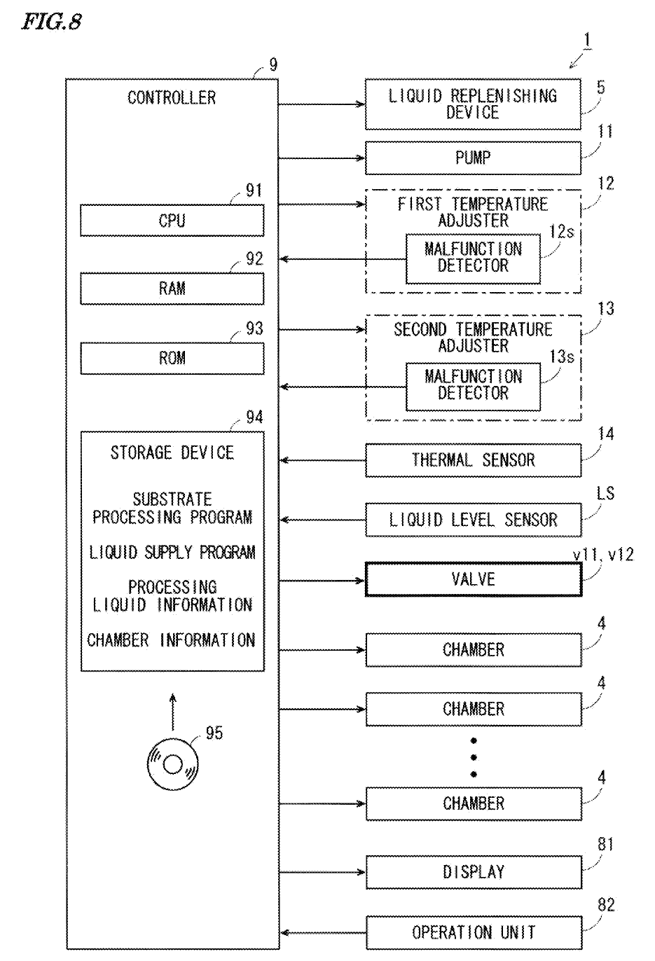

FIG. 8 is a block diagram showing the configuration of a control system of the substrate processing apparatus 1 of FIG. 7. In FIG. 8, the difference from the control system of FIG. 2 according to the first embodiment is indicated by the thick solid lines. As shown in FIG. 8, a controller 9 controls valves v11, v12 in addition to the plurality of constituent elements of the substrate processing apparatus 1 according to the first embodiment.

Specifically, in a period during which the power of the substrate processing apparatus 1 is turned on, the controller 9 puts the valve v11, v12 in the open state regardless of whether a first temperature adjuster 12 and a second temperature adjuster 13 are malfunctioning.

Thus, even in a case in which the number of chambers in which a process is executable changes due to a malfunction of the first temperature adjuster 12 or the second temperature adjuster 13, the processing liquid always flows through each of the circulation pipes p13, p15. That is, even if it is not necessary to supply the processing liquid to the plurality of chambers 4 of one of the two substrate processing sections 3A, 3B because the number of chambers in which a process is executable is set small, the processing liquid always flows through each of the circulation pipes p13, p15. This suppresses a change, due to the stay of the processing liquid, in temperature of the processing liquid in the circulation pipes p13, p15. This further suppresses generation of precipitates due to a change in temperature of the processing liquid. Therefore, it is possible to suppress degradation of temperature quality of the processing liquid in the supply pipe p12 and the circulation pipes p13, p15. Further, it is possible to suppress degradation of the flow state of the processing liquid in the supply pipe p12 and the circulation pipes p13, p15.

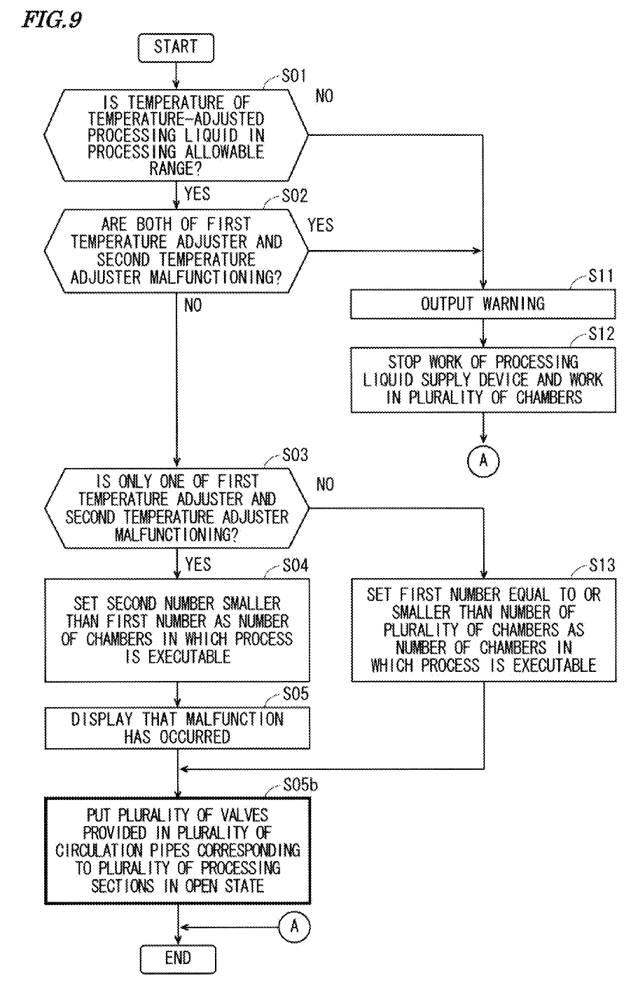

FIG. 9 is a flowchart showing one example of a liquid supply process executed in the substrate processing apparatus 1 according to the third embodiment. In FIG. 9, the difference from the liquid supply process of FIG. 3 according to the first embodiment is indicated by the thick solid lines.

In the liquid supply process according to the present embodiment, a CPU 91 controls the two valves v11, v12 of FIG. 7 after sequentially executing the same process as the process of the steps S01, S02, S03, S04 and S05 of FIG. 3. Alternatively, the CPU 91 controls the two valves v11, v12 of FIG. 7 after sequentially executing the same process as the process of the steps S01, S02, S03 and S13 of FIG. 3. Specifically, the CPU 91 puts the plurality of valves v11, v12 provided in the plurality of circulation pipes p13, p15 corresponding to the plurality (two in the present example) substrate processing sections (step S05b) in an open state, and ends the liquid supply process. In the present embodiment, the process of the step S05b may be executed before the step S01, or may be executed between the step S02 and the step S03.

In the process of the above-mentioned step S05a, even in a case in which the number of chambers in which a process is executable is set small, the processing liquid always flows through each of the plurality of circulation pipes p13, p15 respectively corresponding to the plurality of substrate processing sections 3A, 3B. This can suppress degradation of the temperature quality of the processing liquid circulating through the processing liquid supply device 2 and degradation of the flow state of the processing liquid.

In the present embodiment, the number of chambers in which a process is executable is set in the process of the steps S04 and S13 of FIG. 9. Thus, among the plurality of chambers 4 of the substrate processing sections 3A, 3B, the controller 9 determines, as chambers in which work is to be performed, chambers 4 the number of which is set (the number of chambers in which a process is executable). In the following description, the chambers determined as chambers in which work is to be simultaneously performed is referred to as execution chambers. Then, the controller 9 causes work to be performed in one or a plurality of determined execution chambers, thereby supplying the processing liquid to each of a plurality of substrates W.

In this case, the controller 9 may determine a plurality of execution chambers such that each of the substrate processing sections 3A, 3B includes at least one execution chamber. This reduces generation of a large difference in amount of the processing liquid used in the plurality of substrate processing sections 3A, 3B. This suppresses a significant difference in flow state of the processing liquid in the circulation pipes p13, p15, and suppresses large variations in temperature quality and flow state of the processing liquid circulating through the processing liquid supply device 2.

### 4. Fourth Embodiment

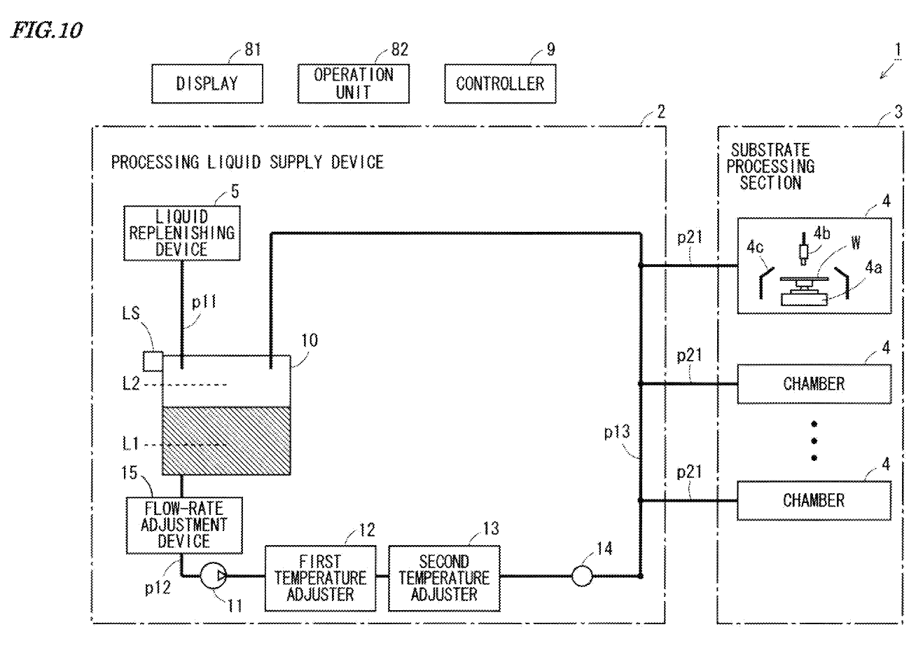

The differences of a substrate processing apparatus 1 according to a fourth embodiment from the substrate processing apparatus 1 according to the first embodiment will be described. FIG. 10 is a schematic configuration diagram of the substrate processing apparatus 1 according to the fourth embodiment. As shown in FIG. 10, in a processing liquid supply device 2 according to the present embodiment, a flow-rate adjustment device 15 is provided in a supply pipe p12. Specifically, the flow-rate adjustment device 15 is provided between the upstream end of the supply pipe p12 and a pump 11, in the supply pipe p12.

The flow-rate adjustment device 15 is a motor needle valve, for example, and is configured to be capable of adjusting a degree of opening according to the number of drive pulses provided from a controller 9. Thus, based on the control of the controller 9, the flow-rate adjustment device 15 adjusts the flow rate of a processing liquid flowing from a storage tank 10 to the supply pipe p12. Hereinafter, the flow rate (an outflow amount per unit time) of the processing liquid flowing from the storage tank 10 to the supply pipe p12 is referred to as a tank outflow amount.

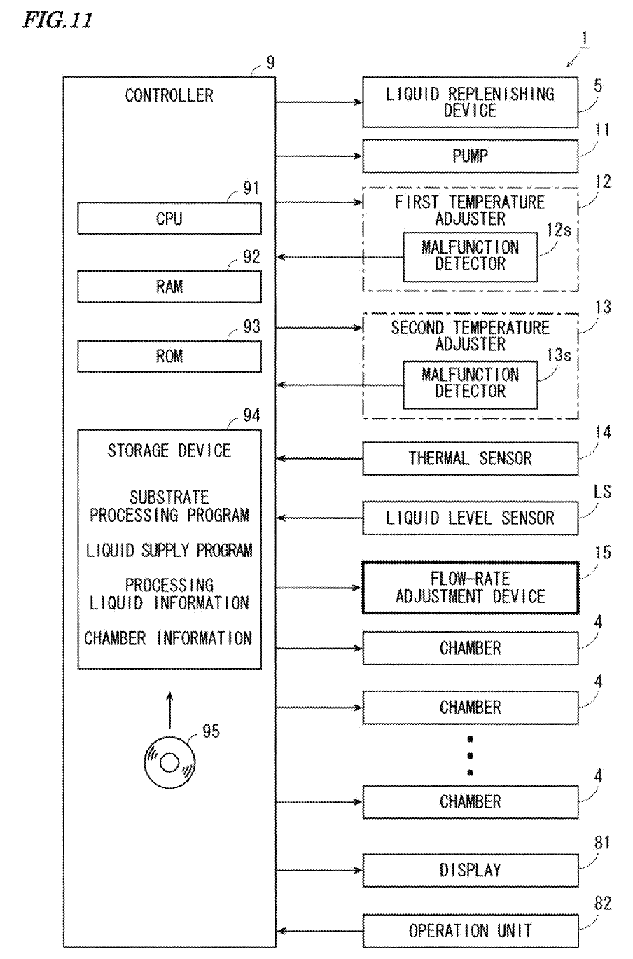

FIG. 11 is a block diagram showing the configuration of a control system of the substrate processing apparatus 1 of FIG. 10. In FIG. 11, the difference from the control system of FIG. 2 according to the first embodiment is indicated by the thick solid lines. As shown in FIG. 11, the controller 9 controls the flow-rate adjustment device 15 in addition to the plurality of constituent elements of the substrate processing apparatus 1 according to the first embodiment.

Specifically, in a case in which neither the first temperature adjuster 12 nor the second temperature adjuster 13 is malfunctioning, the controller 9 controls the flow-rate adjustment device 15 such that a tank outflow amount is a first flow rate. On the other hand, in a case in which only one of the first temperature adjuster 12 and the second temperature adjuster 13 is malfunctioning, the controller 9 controls the flow-rate adjustment device 15 such that the tank outflow amount is a second flow rate that is lower than the first flow rate.

The reason why the tank outflow amount is adjusted in this manner will be described. In the processing liquid supply device 2, a processing liquid circulates through a storage tank 10, a supply pipe p12 and a circulation pipe p13. In a case in which neither the first temperature adjuster 12 nor the second temperature adjuster 13 is malfunctioning, the temperature of the circulating processing liquid is adjusted by the first temperature adjuster 12 and the second temperature adjuster 13. However, when one of the first temperature adjuster 12 and the second temperature adjuster 13 is malfunctioning, efficiency of adjusting the temperature of the processing liquid flowing through the supply pipe p12 is degraded. Therefore, it is likely to be difficult to maintain the temperature of the processing liquid circulating through the processing liquid supply device 2 by using only the other temperature adjuster.

As such, in the present embodiment, the tank outflow amount (second flow rate) when only one temperature adjuster (12, 13) is malfunctioning is set lower than the tank outflow amount (first flow rate) when neither of the two temperature adjusters (12, 13) is malfunctioning. This reduces the flow rate of the processing liquid circulating through the processing liquid supply device 2 and facilitates maintenance of the temperature of the processing liquid. Note that the first flow rate and the second flow rate are preferably set based on an experiment, simulation or the like.

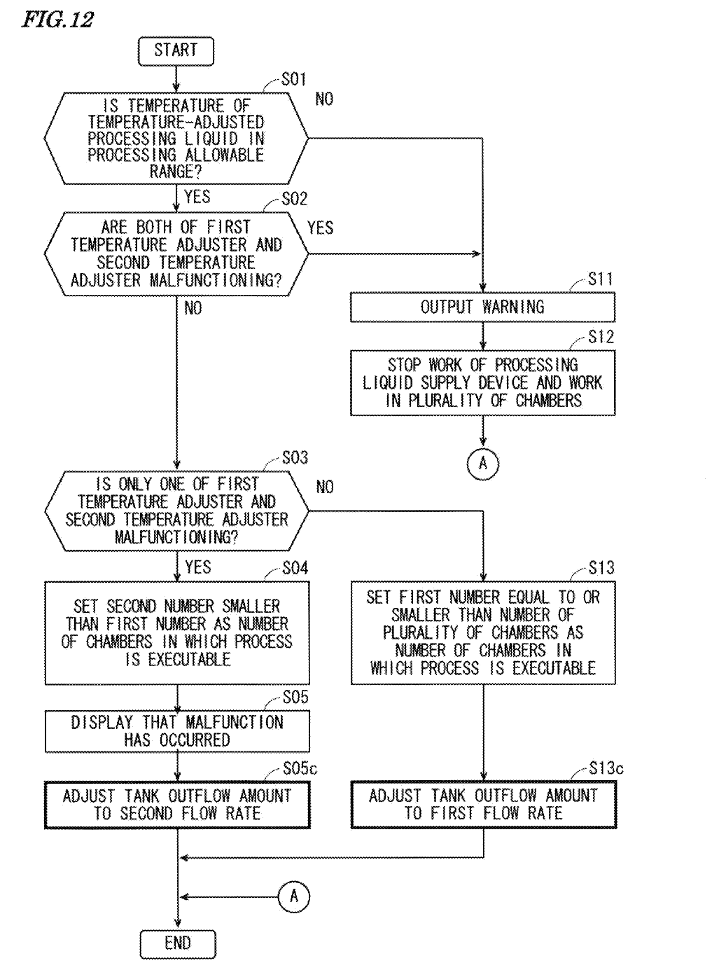

FIG. 12 is a flowchart showing one example of a liquid supply process executed in the substrate processing apparatus 1 according to the fourth embodiment. In FIG. 12, the differences from the liquid supply process of FIG. 3 according to the first embodiment are indicated by the thick solid lines.

In the liquid supply process according to the present embodiment, a CPU 91 controls the flow-rate adjustment device 15 of FIG. 10 after sequentially executing the same process as the process of the steps S01, S02, S03, S04 and S05 of FIG. 3. Specifically, the CPU 91 adjusts the tank outflow amount to the second flow rate lower than the first flow rate (step S05c), and ends the liquid supply process.

Further, in the liquid supply process according to the present embodiment, the CPU 91 controls the flow-rate adjustment device 15 of FIG. 10 after sequentially executing the same process as the process of the steps S01, S02, S03 and S13 of FIG. 3. Specifically, the CPU 91 adjusts the tank outflow amount to the first flow rate higher than the first flow rate (step S13c), and ends the liquid supply process.

With the process of the above-mentioned steps S05c and S13c, the flow rate of the processing liquid circulating through the processing liquid supply device 2 is adjusted according to the capacity to adjust the temperature of the processing liquid by the first temperature adjuster 12 and the second temperature adjuster 13. This facilitates maintenance of the temperature of the processing liquid circulating through the processing liquid supply device 2.

### 5. Fifth Embodiment

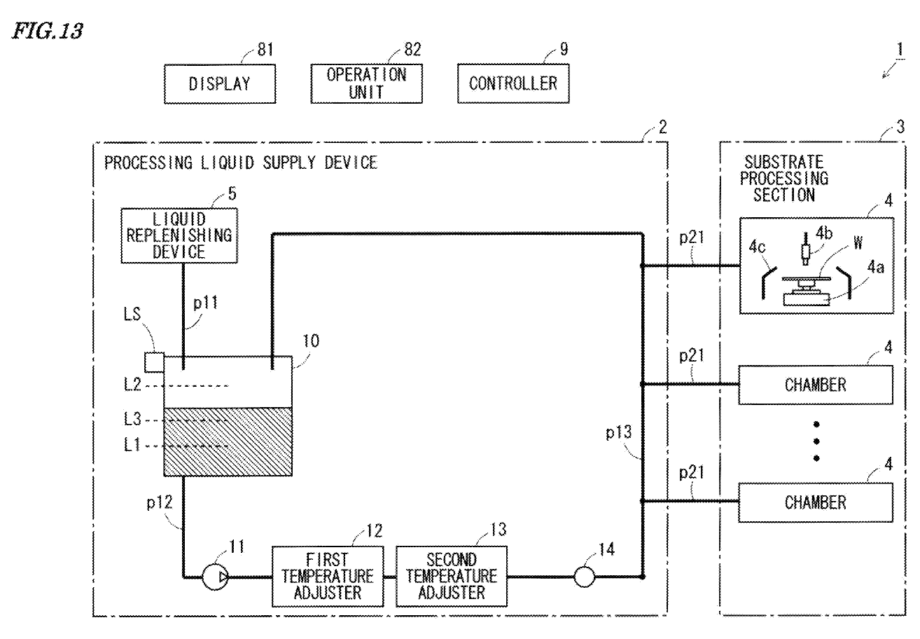

The differences of a substrate processing apparatus 1 according to a fifth embodiment from the substrate processing apparatus 1 according to the first embodiment will be described. FIG. 13 is a schematic configuration diagram of the substrate processing apparatus 1 according to the fifth embodiment. As shown in FIG. 13, the substrate processing apparatus 1 according to the present embodiment has the same configuration as that of the substrate processing apparatus 1 of FIG. 1 according to the first embodiment. However, a processing liquid replenishing function of a processing liquid supply device 2 according to the present embodiment is different from the processing liquid replenishing function of the processing liquid supply device 2 according to the first embodiment.

The processing liquid replenishing function according to the present embodiment will be described below. In a storage tank 10 according to the present embodiment, a malfunction lower limit level L3 is set in addition to a lower limit level L1 and a prescribed level L2 as a plurality of liquid levels for realizing the processing liquid replenishing function. The malfunction lower limit level L3 is higher than the lower limit level L1 and lower than the prescribed level L2.

In the processing liquid replenishing function of the present example, in a case in which neither the first temperature adjuster 12 nor the second temperature adjuster 13 is malfunctioning, the lower limit level L1 is used for determination of start of replenishment with the processing liquid. That is, in a case in which the liquid level of the processing liquid is lowered to the lower limit level L1 in the storage tank 10, a liquid replenishing device 5 works to replenish the storage tank 10 with the processing liquid. Thereafter, when the liquid level of the processing liquid rises to the prescribed level L2, replenishment with the processing liquid is stopped.

On the other hand, in the processing liquid replenishing function of the present example, in a case in which only one of the first temperature adjuster 12 and the second temperature adjuster 13 is malfunctioning, the malfunction lower limit level L3 is used for determination of start of replenishment with the processing liquid. That is, in a case in which the liquid level of the processing liquid is lowered to the malfunction lower limit level L3 in the storage tank 10, the liquid replenishing device 5 works to replenish the storage tank 10 with the processing liquid. Thereafter, when the liquid level of the processing liquid rises to the prescribed level L2, replenishment with the processing liquid is stopped.

The reason why the two types of liquid levels (the lower limit level L1 and the malfunction lower limit level L3) for determining the start of replenishment with the processing liquid are selectively used with the processing liquid replenishing function in this manner will be described. As described in the fourth embodiment, in a case in which neither of the two temperature adjusters (12, 13) is malfunctioning and then one of the two temperature adjusters (12, 13) malfunctions, it degrades efficiency of adjusting the temperature of the processing liquid flowing through the supply pipe p12. Therefore, it is likely to be difficult to maintain the temperature of the processing liquid circulating through the processing liquid supply device 2 by using only the other temperature adjuster.

As such, in the present embodiment, when neither of the two temperature adjusters (12, 13) is malfunctioning, the lower limit level L1 is used as a liquid level for determination of start of replenishment with the processing liquid. In contrast, when only one of the temperature adjusters (12, 13) is malfunctioning, the malfunction lower limit level L3 higher than the lower limit level L1 is used as a liquid level for determining the start of replenishment with the processing liquid.

According to this selective use of the liquid levels, in a case in which only one of the temperature adjusters (12, 13) is malfunctioning, an amount of the processing liquid with which the storage tank 10 is replenished at one time is reduced as compared with a case in which neither of the two temperature adjusters (12, 13) is malfunctioning. This reduces the temperature change amount of the processing liquid in the storage tank 10 due to the replenishment with the processing liquid. As a result, it facilitates maintenance of the temperature of the processing liquid circulating through the processing liquid supply device 2. The lower limit level L1 and the malfunction lower limit level L3 are preferably set based on an experiment, simulation or the like.

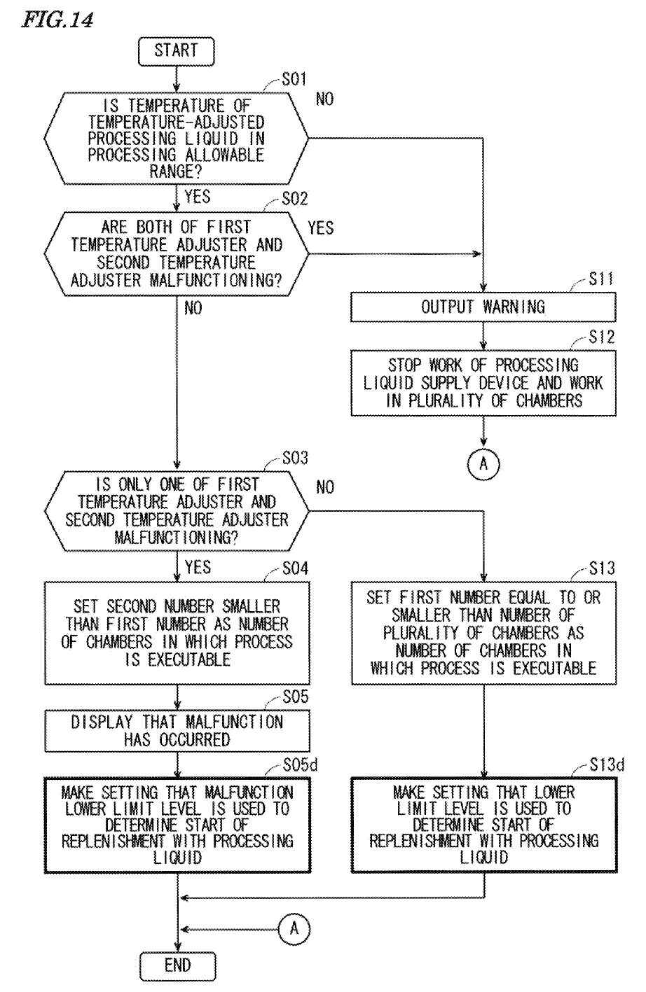

FIG. 14 is a flowchart showing one example of a liquid supply process executed in the substrate processing apparatus 1 according to the fifth embodiment. In FIG. 14, the differences from the liquid supply process of FIG. 3 according to the first embodiment are indicated by the thick solid lines.

In the liquid supply process according to the present embodiment, a CPU 91 sets a liquid level for determining the start of replenishment with the processing liquid using the processing liquid replenishing function after sequentially executing the same process as the process of the steps S01, S02, S03, S04 and S05 of FIG. 3. Specifically, the CPU 91 makes setting that the malfunction lower limit level L3 higher than the lower limit level L1 is to be used to determine the start of replenishment with the processing liquid (step S05d), and ends the liquid supply process.

Further, in the liquid supply process according to the present embodiment, the CPU 91 sets a liquid level for determining the start of replenishment with the processing liquid using the processing liquid replenishing function after sequentially executing the same process as the process of the steps S01, S02, S03 and S13 of FIG. 3. Specifically, the CPU 91 makes setting that the lower limit level L1 lower than the malfunction lower limit level L3 is to be used to determine the start of replenishment with the processing liquid (step S13d), and ends the liquid supply process.

With the process of the steps S05d and S13d, an amount of the processing liquid with which the storage tank 10 is replenished at one time is adjusted according to the capacity to adjust the temperature of the processing liquid using the first temperature adjuster 12 and the second temperature adjuster 13. This facilitates maintenance of the temperature of the processing liquid circulating through the processing liquid supply device 2.

In the liquid supply process according to the present embodiment, the following process may be executed instead of the setting made in in the step S05d that the malfunction lower limit level L3 is used for determination of start of replenishment with the processing liquid. For example, as the process of the step S05d, regardless of a liquid level of the processing liquid, setting may be made that the storage tank 10 is continuously replenished with the processing liquid at a predetermined flow rate with the processing liquid being supplied from the liquid replenishing device 5. In this case, the flow rate of the processing liquid supplied from the liquid replenishing device 5 to the storage tank 10 is preferably set lower than the flow rate of the processing liquid supplied from the liquid replenishing device 5 to the storage tank 10 in the process of the step S05d. With execution of these processes, an amount of the processing liquid with which the storage tank 10 is replenished at one time is adjusted similarly to the above-mentioned example. This facilitates maintenance of the temperature of the processing liquid circulating through the processing liquid supply device 2.

### 6. Sixth Embodiment

The differences of a substrate processing apparatus 1 according to a sixth embodiment from the substrate processing apparatus 1 according to the first embodiment will be described. The substrate processing apparatus 1 according to the present embodiment has the same configuration as the substrate processing apparatus 1 of FIG. 1 according to the first embodiment. However, a processing liquid replenishing function of a processing liquid supply device 2 according to the present embodiment is different from the processing liquid replenishing function of the processing liquid supply device 2 according to the first embodiment.

The processing liquid replenishing function according to the present embodiment will be described below. Here, suppose that a liquid replenishing device 5 according to the present embodiment is configured to be capable of adjusting the flow rate of a processing liquid when a storage tank 10 is replenished with the processing liquid supplied from a replenishing pipe p11 based on the control of a controller 9. As such, with the processing liquid replenishing function of the present example, in a case in which neither a first temperature adjuster 12 nor a second temperature adjuster 13 is malfunctioning, the flow rate of the processing liquid with which the storage tank 10 is replenished and which is supplied from the liquid replenishing device 5 is adjusted to a first replenishment flow rate.

On the other hand, with the processing liquid replenishing function of the present example, in a case in which only one of the first temperature adjuster 12 and the second temperature adjuster 13 is malfunctioning, the flow rate of the processing liquid with which the storage tank 10 is replenished and which is supplied from the liquid replenishing device 5 is adjusted to a second replenishment flow rate lower than the first replenishment flow rate.

The reason why the flow rate of the processing liquid with which the storage tank 10 is replenished and which is supplied from the liquid replenishing device 5 is adjusted in this manner using the processing liquid replenishing function will be described. As described in the fourth embodiment, in a case in which neither of the two temperature adjusters (12, 13) is malfunctioning and then one of the two temperature adjusters (12, 13) malfunctions, it degrades efficiency of adjusting the temperature of the processing liquid flowing through the supply pipe p12. Therefore, it is likely to be difficult to maintain the temperature of the processing liquid circulating through the processing liquid supply device 2 by using only the other temperature adjuster.

As such, in the present embodiment, when neither of the two temperature adjusters (12, 13) is malfunctioning, the flow rate of the processing liquid with which the storage tank 10 is replenished and which is supplied from the liquid replenishing device 5 is adjusted to the first replenishment flow rate. In contrast, when only one of the temperature adjusters (12, 13) is malfunctioning, the flow rate of the processing liquid with which the liquid replenishing device 5 is replenished and which is supplied from the liquid replenishing device 5 is adjusted to the second replenishment flow rate lower than the first replenishment flow rate.

According to this selective use of the replenishment flow rates, in a case in which only one of the temperature adjusters (12, 13) is malfunctioning, an amount of the processing liquid with which the storage tank is replenished per unit time is reduced as compared with a case in which neither of the two temperature adjusters (12, 13) is malfunctioning. This reduces the temperature change amount of the processing liquid in the storage tank 10 per unit time due to the replenishment with the processing liquid. As a result, it facilitates maintenance of the temperature of the processing liquid circulating through the processing liquid supply device 2. The first replenishment flow rate and the second replenishment flow rate are preferably set based on an experiment, simulation or the like.

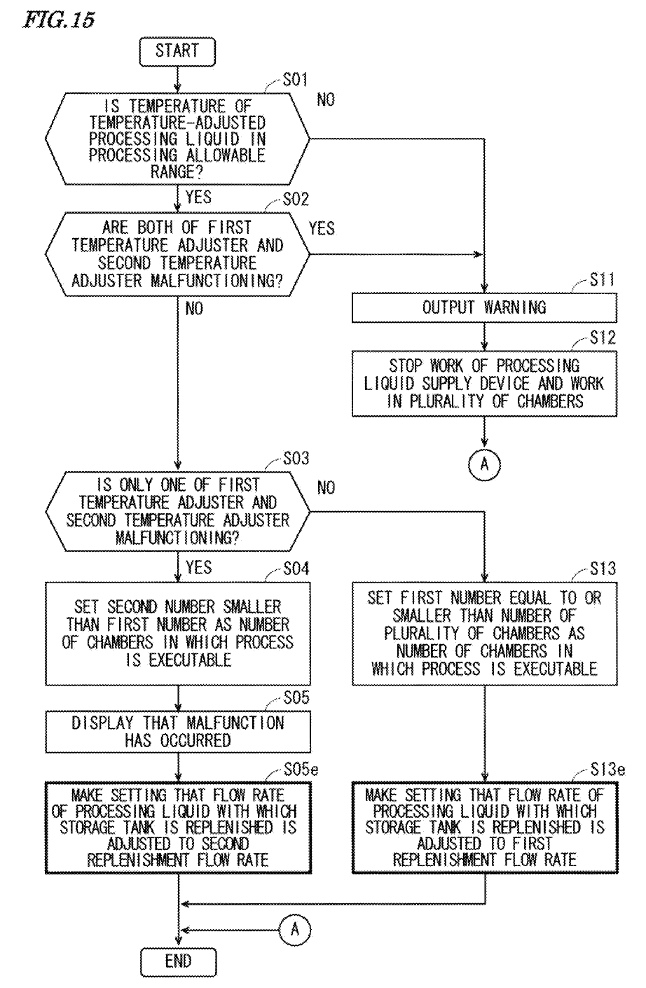

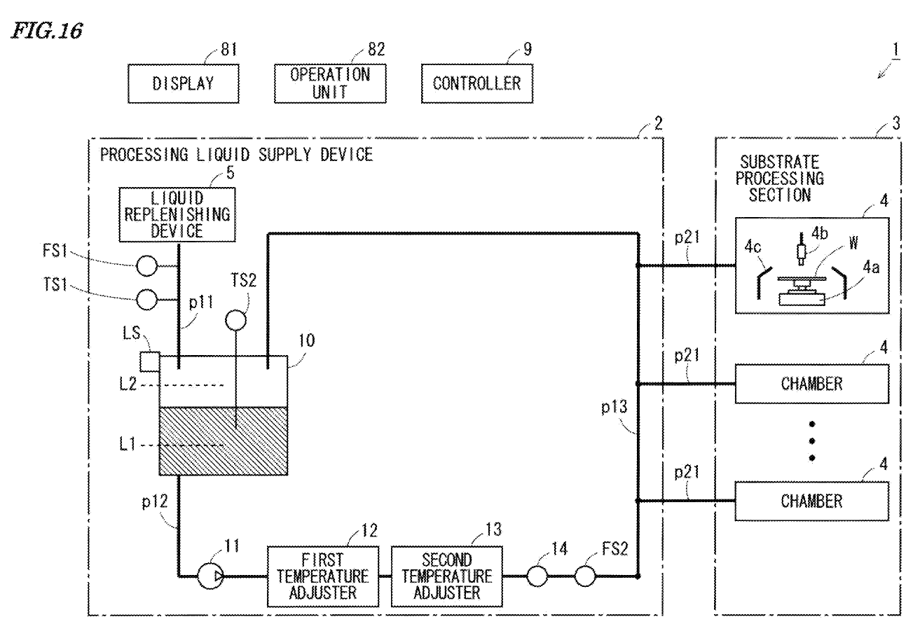

FIG. 15 is a flowchart showing one example of a liquid supply process executed in the substrate processing apparatus 1 according to the sixth embodiment. In FIG. 16, the differences from the liquid supply process of FIG. 3 according to the first embodiment are indicated by the thick solid lines.

In the liquid supply process according to the present embodiment, a CPU 91 sets the flow rate of the processing liquid with which the storage tank is replenished by the processing liquid replenishing function after sequentially executing the same process as the process of the steps S01, S02, S03, S04 and S05 of FIG. 3. Specifically, the CPU 91 makes setting that the flow rate of the processing liquid with which the storage tank 10 is replenished is adjusted to the second replenishing flow rate lower than the first replenishing flow rate (step S05e), and ends the liquid supply process.

Further, in the liquid supply process according to the present embodiment, the CPU 91 sets the flow rate of the processing liquid with which the storage tank is replenished by the processing liquid replenishing function after sequentially executing the same process as the process of the steps S01, S02, S03 and S13 of FIG. 3. Specifically, the CPU 91 makes setting that the flow rate of the processing liquid with which the storage tank 10 is replenished is adjusted to the first replenishing flow rate higher than the second replenishing flow rate (step S13e), and ends the liquid supply process.

With the process of the above-mentioned steps S05e and S13e, an amount of the processing liquid with which the storage tank 10 is replenished is adjusted according to the capacity to adjust the temperature of the processing liquid by the first temperature adjuster 12 and the second temperature adjuster 13. This facilitates maintenance of the temperature of the processing liquid circulating through the processing liquid supply device 2.

In the liquid supply process according to the present embodiment, the following process may be executed in addition to the setting that the flow rate of the processing liquid with which the storage tank 10 is replenished is adjusted to the second replenishing flow rate lower than the first replenishing flow rate in the step S05e. For example, in addition to the adjustment of the flow rate of the processing liquid with which the storage tank 10 is replenished to the second replenishing flow rate as the process of the step S05e, setting may be made that the storage tank 10 is continuously replenished with the processing liquid supplied from the liquid replenishing device 5 (constant replenishment) regardless of the liquid level of the processing liquid. In this case, an amount of the processing liquid with which the storage tank 10 is replenished at one time is adjusted. This facilitates maintenance of the temperature of the processing liquid circulating through the processing liquid supply device 2.

### 7. Seventh Embodiment

The differences of a substrate processing apparatus 1 according to a seventh embodiment from the substrate processing apparatus 1 according to the first embodiment will be described. FIG. 16 is a schematic configuration diagram of the substrate processing apparatus 1 according to the seventh embodiment. As shown in FIG. 16, in a processing liquid supply device 2 according to the present embodiment, a flow-rate sensor FS1 and a thermal sensor TS1 are provided in a replenishing pipe p11. The flow-rate sensor FS1 detects the flow rate of a processing liquid flowing through the replenishing pipe p11, and outputs a flow-rate signal indicating the detected flow rate to a controller 9. The thermal sensor TS1 detects a temperature of the processing liquid in the replenishing pipe p11, and outputs a temperature signal indicating the detected temperature of the processing liquid to the controller 9.

Further, in the processing liquid supply device 2 of the present example, a thermal sensor TS2 is provided in a storage tank 10. The thermal sensor TS2 detects a temperature of the processing liquid stored in the storage tank 10, and outputs a temperature signal indicating the detected temperature of the processing liquid to the controller 9.

Further, in the processing liquid supply device 2 of the present example, a flow-rate sensor FS2 is provided in a supply pipe p12. The flow-rate sensor FS2 detects a flow rate of the processing liquid flowing through the supply pipe p12, and outputs a flow-rate signal indicating the detected flow rate to the controller 9.

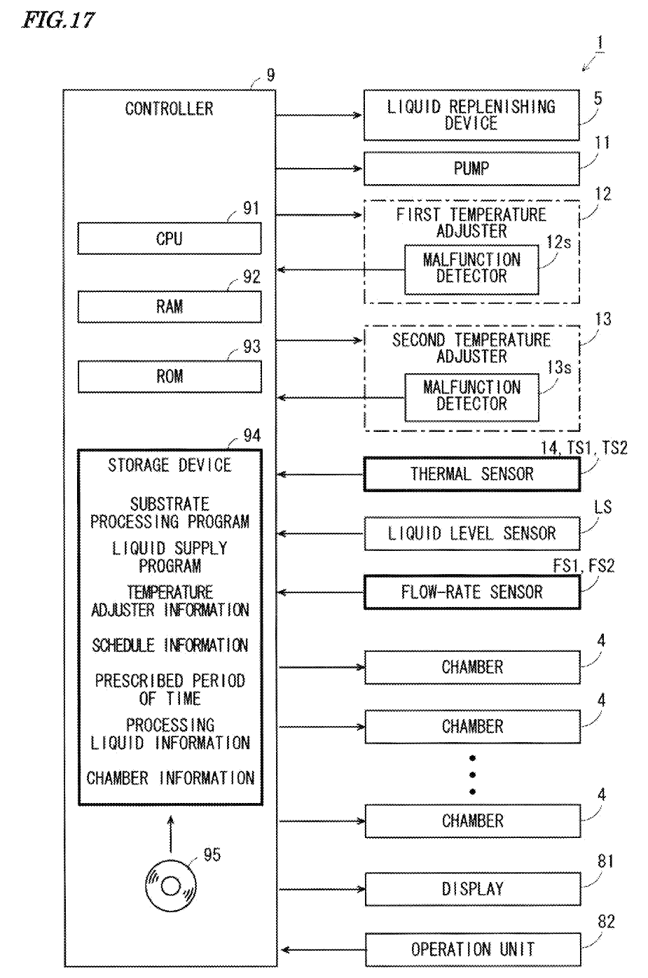

FIG. 17 is a block diagram showing the configuration of a control system of the substrate processing apparatus 1 of FIG. 16. In FIG. 17, the differences from the control system of FIG. 2 according to the first embodiment are indicated by the thick solid lines. As shown in FIG. 17, the controller 9 receives temperature signals output from the thermal sensors TS1, TS2 of FIG. 16 in addition to a temperature signal output from a thermal sensor 14. Further, the controller 9 receives flow-rate signals output from the flow-rate sensors FS1, FS2 of FIG. 16.

Further, in the controller 9 according to the present embodiment, temperature adjuster information is stored in a storage device 94. The temperature adjuster information represents temperature adjustment capacity of a first temperature adjuster 12 and a second temperature adjuster 13. Specifically, the temperature adjuster information represents an amount of work that can be output per unit time by each of the first temperature adjuster 12 and the second temperature adjuster 13. The temperature adjuster information is stored in the storage device 94 in advance by a user operation of an operation unit 82 before the process for a plurality of substrates W is started.

Further, in the controller 9 according to the present embodiment, schedule information is stored in the storage device 94. The schedule information represents the contents of a process scheduled to be executed in a plurality of chambers 4 and the number of substrates W scheduled to be processed. The schedule information is stored in the storage device 94 in advance by a user operation of the operation unit 82 before the process for a plurality of substrates W is started. The schedule information includes, as the processing contents, information representing an amount of the processing liquid required in one chamber 4 for processing one substrate W. Therefore, an amount of the processing liquid to be consumed in a substrate processing section 3 can be calculated based on the schedule information and the number of chambers in which a process is executable.

Further, in the controller 9 according to the present embodiment, a prescribed period is stored in the storage device 94. The prescribed period is stored in the storage device 94 in advance by a user operation of the operation unit 82 before the plurality of substrates W are processed. The prescribed period is used to define a consumable amount, described below.

In the substrate processing apparatus 1 according to the first embodiment, the number of chambers in which a process is executable is set to either the first number or the second number according to the malfunction states of the first temperature adjuster 12 and the second temperature adjuster 13. However, in a case in which only one of the first temperature adjuster 12 and the second temperature adjuster 13 is malfunctioning, the appropriate number of chambers in which a process is executable is considered to dynamically change depending on the state of the processing liquid circulating through the processing liquid supply device 2 and the state of the processing liquid with which the storage tank 10 is replenished in the processing liquid supply device 2.

As such, in the present embodiment, in a case in which only one of the first temperature adjuster 12 and the second temperature adjuster 13 is malfunctioning, an appropriate number of chambers in which a process is executable is sequentially calculated in consideration of the temperature adjustment capacity of the first temperature adjuster 12 and the second temperature adjuster 13, the circulation state of the processing liquid through the processing liquid supply device 2, and the replenishment state of the processing liquid. Thus, a set value for the number of chambers in which a process is executable is updated at predetermined time intervals.

A method of calculating the appropriate number of chambers in which a process is executable will be described. In the following description, the estimated maximum amount of the processing liquid that can be supplied from the processing liquid supply device 2 to the substrate processing section 3 while the temperature of the processing liquid supplied to the substrate processing section 3 is maintained in a processing allowable range from a current point in time until the prescribed period elapses is referred to as a consumable amount. Further, the state in which only one of the first temperature adjuster 12 and the second temperature adjuster 13 is malfunctioning is suitably referred to as a one-adjuster malfunctioning state.

In order to calculate the appropriate number of chambers in which a process is executable, it is necessary to identify a consumable amount. A consumable amount can be estimated based on the temperature adjuster information, the state of the processing liquid circulating through the processing liquid supply device 2, and the state of the processing liquid with which the storage tank 10 is replenished in the processing liquid supply device 2, for example.

As such, in the present embodiment, in the one-adjuster malfunctioning state, a plurality of physical quantities indicating the state of the processing liquid circulating through the processing liquid supply device 2 are acquired as circulation information. Specifically, the circulation information includes an amount of the processing liquid in the storage tank 10 calculated based on a detection result provided by a liquid level sensor LS and the design dimensions of the storage tank 10. Further, the circulation information includes a temperature detected by the thermal sensor TS2 (a temperature of the processing liquid in the storage tank 10). Further, the circulation information includes a temperature detected by the thermal sensor 14 (a temperature of the temperature-adjusted processing liquid flowing through the supply pipe p12). Further, the circulation information includes a flow rate detected by the flow-rate sensor FS2 (a flow rate of the processing liquid flowing through the supply pipe p12).

Further, in the present embodiment, in the one-adjuster malfunctioning state, a plurality of physical quantities indicating the state of the processing liquid with which the storage tank 10 is replenished in the processing liquid supply device 2 are acquired as replenishment information. Specifically, the replenishment information includes a temperature detected by the thermal sensor TS1 (a temperature of the processing liquid flowing through the replenishing pipe p11). Further, the replenishment information includes a flow rate detected by the flow-rate sensor FS1 (a flow rate of the processing liquid flowing through the replenishing pipe p11).

Thus, a consumable amount is estimated based on the temperature adjuster information stored in the storage device 94 and the detection results provided by the plurality of sensors (14, FS1, FS2, LS, TS1, TS2). Thereafter, based on the estimated consumable amount and the schedule information stored in the storage device 94, the maximum number of the chambers 4 in which work can be simultaneously performed is calculated as an appropriate number of chambers in which a process is executable. For example, the appropriate number of chambers in which a process is executable can be obtained by division of the estimated consumable amount by an amount of the processing liquid required for processing one substrate W that is scheduled to be processed after a current point in time.

The length of the prescribed period may be set to about several seconds (2 seconds, 3 seconds or the like) or may be set to about several minutes (10 minutes, 30 minutes or the like).

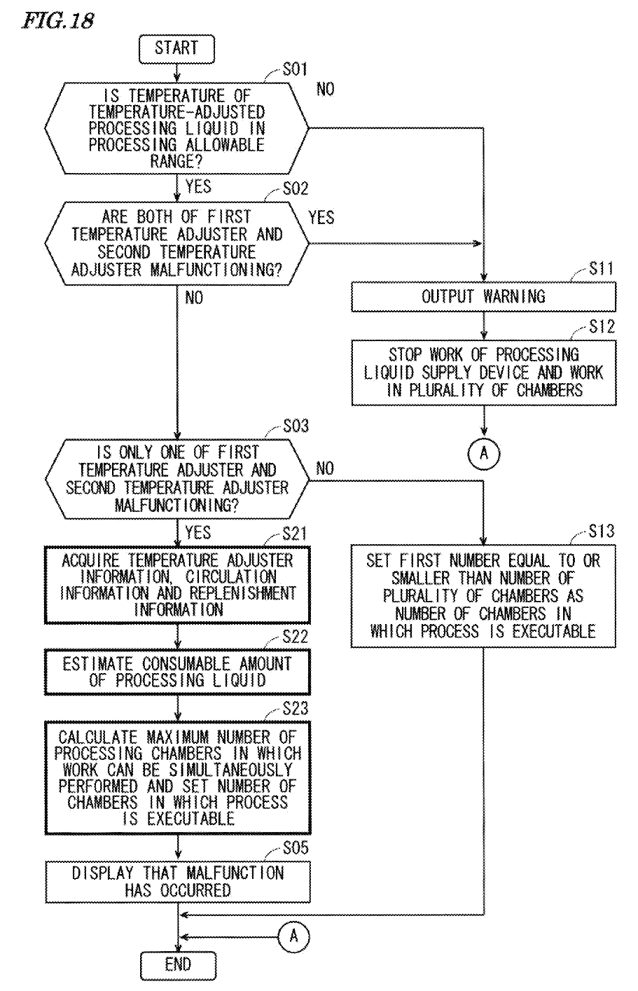

FIG. 18 is a flowchart showing one example of a liquid supply process executed in the substrate processing apparatus 1 according to the seventh embodiment. In FIG. 18, the differences from the liquid supply process of FIG. 3 according to the first embodiment are indicated by the thick solid lines.

As shown in FIG. 18, in a case in which only one of the first temperature adjuster 12 and the second temperature adjuster 13 is malfunctioning in the same process as the step S03 of FIG. 3, the CPU 91 acquires temperature adjuster information, circulation information and replenishment information (step S21).

Specifically, the CPU 91 acquires the temperature adjuster information stored in the storage device 94. Further, based on the detection results of the plurality of sensors (14, FS2, LS, TS2), the CPU 91 acquires, as the circulation information, an amount of the processing liquid in the storage tank 10, a temperature of the processing liquid in the storage tank 10, a temperature of the temperature-adjusted processing liquid flowing through the supply pipe p12 and a flow rate of the processing liquid flowing through the supply pipe p12. Further, based on the detection results of the plurality of sensors (FS1, TS1), the CPU 91 acquires a temperature of the processing liquid flowing through the replenishing pipe p11 and a flow rate of the processing liquid flowing through the replenishing pipe p11 as the replenishment information.

Next, based on the acquired temperature adjuster information, the acquired circulation information and the acquired replenishment information, the prescribed period stored in the storage device 94 and processing liquid information stored in the storage device 94, the CPU 91 estimates a consumable amount of the processing liquid (step S22).

Next, based on the estimated consumable amount, and the scheduled information stored in the storage device 94, the CPU 91 calculates the maximum number of chambers 4 in which work can be simultaneously performed in the substrate processing section 3 and sets the calculated number as the number of chambers in which a process is executable (step S23).

Thereafter, the CPU 91 causes the display 81 to display that one of the first temperature adjuster 12 and the second temperature adjuster 13 is malfunctioning (step S05), and ends the liquid supply process.

In the process of the above-mentioned steps S21 to S23, in a case in which only one of the first temperature adjuster 12 and the second temperature adjuster 13 is malfunctioning, a consumable amount is estimated based on the temperature adjuster information, the circulation information and the replenishment information. Based on the estimated consumable amount and the schedule information, an appropriate number of chambers in which a process is executable is calculated. As a result, degradation of processing efficiency of the substrate W is alleviated.

Similarly to the liquid supply process according to the first embodiment, the liquid supply process according to the present embodiment is also started when the power of the substrate processing apparatus 1 turned on, and is repeatedly executed each time a predetermined period of time elapses. Here, it is preferable that the time interval of the liquid supply process repeated in the present embodiment is set as small as possible (about several seconds, for example). Thus, when the processing liquid supply device 2 is in the one-adjuster malfunctioning state, an appropriate number of chambers in which a process is executable is determined and updated substantially in real time.

### 8. Eighth Embodiment

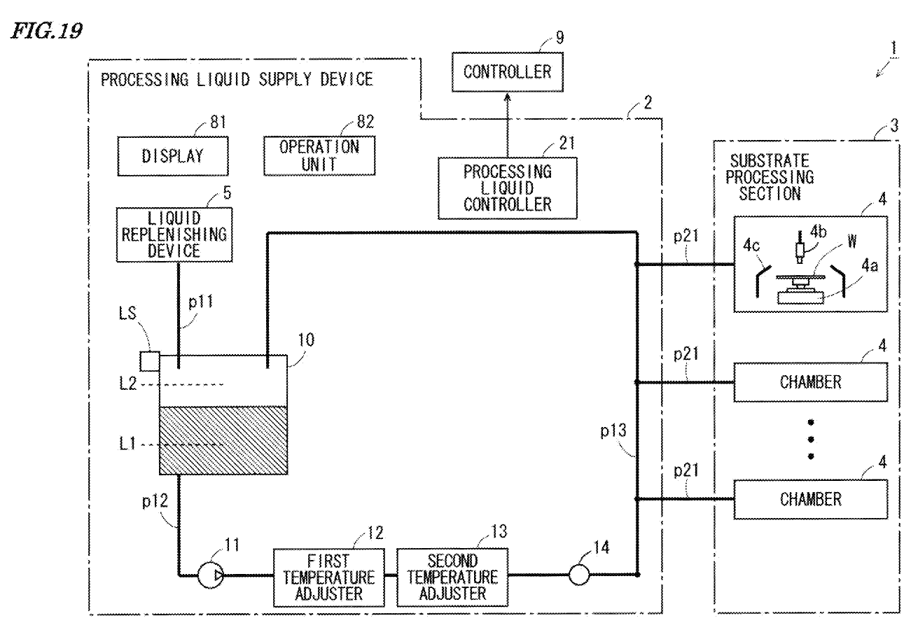

The differences of a substrate processing apparatus 1 according to an eighth embodiment from the substrate processing apparatus 1 according to the first embodiment will be described. FIG. 19 is a schematic configuration diagram of the substrate processing apparatus 1 according to the eighth embodiment. As shown in FIG. 19, in the substrate processing apparatus 1 according to the present embodiment, a processing liquid supply device 2 includes a display 81 and an operation unit 82. Further, the processing liquid supply device 2 further includes a processing liquid controller 21 that is separate from a controller 9 of the substrate processing apparatus 1 and controls the work of each constituent element of the processing liquid supply device 2.

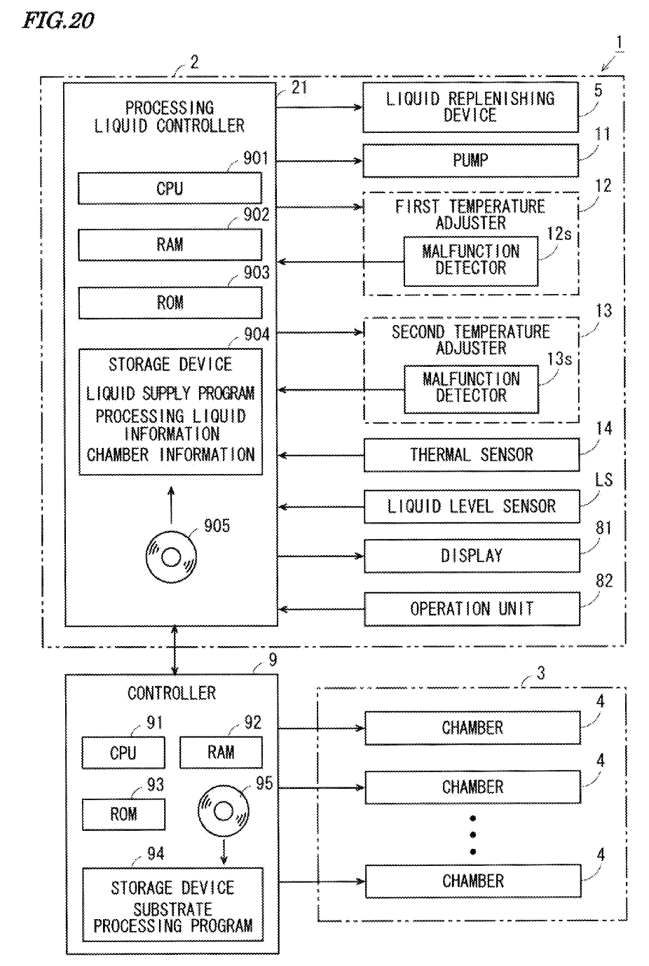

FIG. 20 is a block diagram showing the configuration of a control system of the substrate processing apparatus 1 of FIG. 19. As shown in FIG. 20, the processing liquid controller 21 includes a CPU 901, a RAM 902, a ROM 903 and a storage device 904, similarly to the controller 9.

The RAM 902 is used as a work area for the CPU 901. A system program is stored in the ROM 903. The storage device 904 includes a storage medium such as a hard disc or a semiconductor memory, and stores a liquid supply program, processing liquid information and chamber information.

The liquid supply program may be provided in the state of being stored in a recording medium such as a CD-ROM 905 and installed in the ROM 903 or the storage device 904. Alternatively, the liquid supply program may be distributed from a server outside of the substrate processing apparatus 1 through a communication network, and installed in the ROM 903 or the storage device 904. The CPU 901 of the processing liquid controller 21 executes the liquid supply program, so that a necessary amount of the processing liquid is supplied from the processing liquid supply device 2 to a substrate processing section 3.

Further, in the present embodiment, the storage device 94 of the controller 9 stores a substrate processing program. Further, the CPU 91 of the controller 9 executes the substrate processing program, so that the work of each component of the substrate processing section 3 is controlled, and substrate processing using a processing liquid is executed in a plurality of chambers 4.

In the substrate processing apparatus 1 according to the present embodiment, the processing liquid controller 21 controls the work of each component of the processing liquid supply device 2. Further, as a process corresponding to a first temperature management function, the processing liquid controller 21 outputs an instruction signal for stopping the work of the substrate processing section 3 in a case in which a temperature detected by a thermal sensor 14 is out of a processing allowable range. Further, as a process corresponding to a second temperature management function, the processing liquid controller 21 outputs an instruction signal for stopping the work of the substrate processing section 3 in a case in which both of the first temperature adjuster 12 and the second temperature adjuster 13 are malfunctioning.

Further, as a process corresponding to an exclusive processing function, the processing liquid controller 21 outputs the number of chambers in which a process is executable and which is set according to the malfunction states of the first temperature adjuster 12 and the second temperature adjuster 13.

The controller 9 receives various signals output from the processing liquid controller 21 to stop the substrate processing section 3 or perform exclusive control of the plurality of chambers 4 based on the number of chambers in which a process is executable.

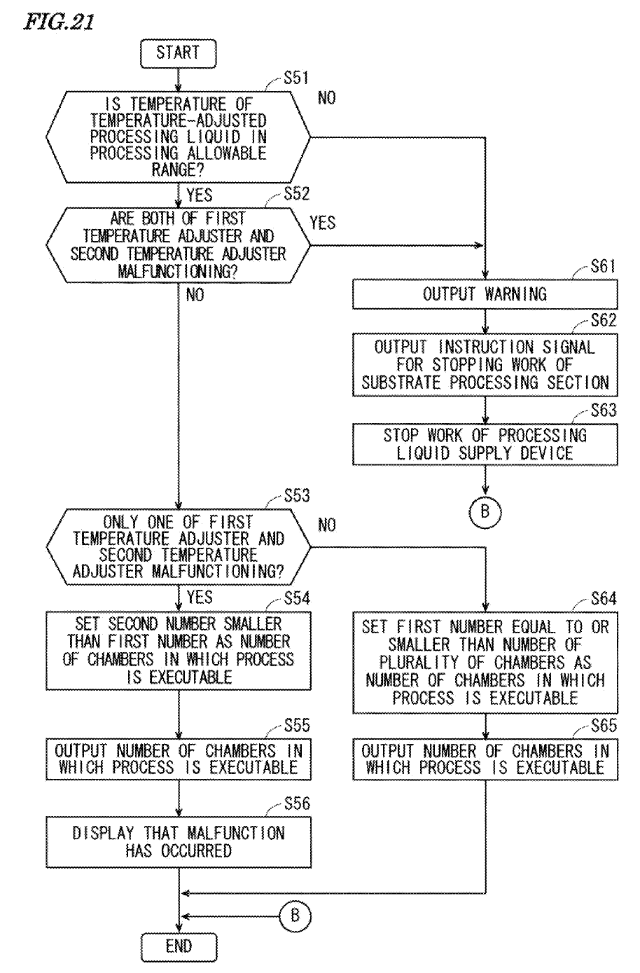

FIG. 21 is a flowchart showing one example of a liquid supply process executed in the processing liquid supply device 2 according to the eighth embodiment. The below-mentioned liquid supply process is executed when the CPU 901 of the processing liquid controller 21 executes a liquid supply program stored in the storage device 904 while utilizing the RAM 902 as a work area.

Similarly to the liquid supply process according to the first embodiment, the liquid supply process according to the present embodiment is also started when the power of the substrate processing apparatus 1 turned on and is repeatedly executed each time a predetermined period of time elapses. When the liquid supply process is started, the CPU 901 determines whether the temperature of the temperature-adjusted processing liquid is in the processing allowable range based on a temperature signal output from the thermal sensor 14 (step S51).

In a case in which the temperature of the temperature-adjusted processing liquid is in the processing allowable range, the CPU 901 determines whether both of the first temperature adjuster 12 and the second temperature adjuster 13 are malfunctioning based on whether malfunction signals are output from malfunction detectors 12s, 13s (step S52). In other words, the CPU 91 determines whether at least one of the first temperature adjuster 12 and the second temperature adjuster 13 is not malfunctioning.

In a case in which at least one of the first temperature adjuster 12 and the second temperature adjuster 13 is not malfunctioning, the CPU 901 determines whether only one of the first temperature adjuster 12 and the second temperature adjuster 13 is malfunctioning (step S53).

When neither the first temperature adjuster 12 nor the second temperature adjuster is malfunctioning, the CPU 901 sets a first number equal to or smaller than the number of the plurality of chambers 4 of the substrate processing section 3 as the number of chambers in which a process is executable (step S64), and outputs the number of chambers in which a process is executable (step S65). Thereafter, the CPU 901 ends the liquid supply process.

In the step S53, in a case in which only one of the first temperature adjuster 12 and the second temperature adjuster 13 is malfunctioning, the CPU 901 sets a second number smaller than the first number as the number of chambers in which a process is executable (step S54), and outputs the number of chambers in which a process is executable (step S55).

Next, the CPU 901 causes the display 81 to display that one of the first temperature adjuster 12 and the second temperature adjuster 13 is malfunctioning (step S56), and ends the liquid supply process.

Description will be made in regard to a case in which the temperature of the temperature-adjusted processing liquid is not in the processing allowable range in the process of the step S51, and a case in which both of the first temperature adjuster 12 and the second temperature adjuster 13 are malfunctioning in the process of the step S52. In these cases, the CPU 901 outputs a warning (step S61). Thereafter, the CPU 901 outputs an instruction signal for stopping the work of the substrate processing section 3 (step S62). Further, the CPU 901 stops the work of the processing liquid supply device 2 (step S63), and ends the liquid supply process.

The CPU 91 of the controller 9 controls each chamber 4 of the substrate processing section 3 based on the substrate processing program stored in the storage device 94 and various signals output from the CPU 901 of the processing liquid controller 21. Thus, a process using a processing liquid is executed on the plurality of substrates W in the chambers 4 the number of which is set in either the step S54 or the step S64 of the liquid supply process.

Also in the present embodiment, in a case in which one of the first temperature adjuster 12 and the second temperature adjuster 13 is malfunctioning and the other one of the first temperature adjuster 12 and the second temperature adjuster 13 is not malfunctioning, the second number smaller than the first number is set as the number of chambers in which a process is executable. Thus, it is possible to reduce the possibility that the work of the processing liquid supply device 2 and the work in all of the plurality of chambers 4 are stopped due to the first temperature management function at an unintended point in time.

### 9. Other Embodiments

(a) While the processing liquid supply device 2 according to the above-mentioned embodiment supplies a chemical liquid for etching a substrate W to the substrate processing section 3 as one example of a processing liquid, the present disclosure is not limited to this. The processing liquid may be a rinse liquid for rinsing the upper surface of the substrate W. That is, the processing liquid supply device 2 may be configured to be capable of supplying the rinse liquid to the substrate processing section 3. Alternatively, the processing liquid may be a replacement liquid for removing the chemical liquid remaining on the upper surface of the substrate W. That is, the processing liquid supply device 2 may be configured to be capable of supplying the replacement liquid to the substrate processing section 3.
(b) In the processing liquid supply device 2 according to the above-mentioned embodiment, each of the replenishing pipe p11, the supply pipe p12, the circulation pipe p13, the bypass pipe p14, the circulation pipe p15 and the chamber pipes p21, p22 is only required to form a flow path of the processing liquid. Therefore, each pipe (p11, p12, p13, p14, p15, p21, p22) according to the above-mentioned embodiment may be formed of a plurality of pipes and one or a plurality of joints.
(c) While the temperature of the processing liquid supplied from the processing liquid supply device 2 to the substrate processing section 3 is adjusted by the first temperature adjuster 12 and the second temperature adjuster 13 in the substrate processing apparatus 1 according to the above-mentioned embodiment, the present disclosure is not limited to this. In the processing liquid supply device 2, the number of temperature adjusters that adjust a temperature of the processing liquid is only required to be equal to or larger than two. Therefore, the processing liquid supply device 2 may include three or more temperature adjusters including the first temperature adjuster 12 and the second temperature adjuster 13. In this case, the substrate processing apparatus 1 may be configured such that the work of the processing liquid supply device 2 and the work of the substrate processing section 3 are stopped when all of the plurality of temperature adjusters are malfunctioning. Further, the substrate processing apparatus 1 may be configured such that, each time the number of temperature adjusters that are malfunctioning increases, the number of chambers in which a process is executable sequentially decreases.
(d) While the substrate processing apparatus 1 according to the third embodiment includes the two substrate processing sections 3A, 3B, the present disclosure is not limited to this. The substrate processing apparatus 1 according to the third embodiment may include three or more substrate processing sections including the two substrate processing sections 3A, 3B. In this case, in the substrate processing apparatus 1, a plurality of circulation pipes respectively corresponding to the plurality of substrate processing sections are provided. In this case, it is preferable that the processing liquid always flows through the plurality of circulation pipes in a period during which the power of the substrate processing apparatus 1 is turned on.
(e) The substrate processing apparatuses 1 according to the first to seventh embodiments include features different from one another. Therefore, the plurality of features described in the first to seventh embodiments may be suitably combined. For example, the parallel arrangement of the first temperature adjuster 12 and the second temperature adjuster 13 and the method of controlling the valves v01, v02 according to the second embodiment may be applied to the substrate processing apparatuses 1 according to the third to seventh embodiments. Further, the configuration and the control method for adjusting a tank outflow amount of a processing liquid using the flow-rate adjustment device 15 according to the fourth embodiment may be applied to the substrate processing apparatuses 1 according to the first to third embodiments and the fifth to seventh embodiments.
(f) In the substrate processing apparatus 1 according to the eighth embodiment, the processing liquid supply device 2 includes the processing liquid controller 21, the display 81 and the operation unit 82. Further, the processing liquid controller 21 functions as part of the controller 9 according to the first embodiment. However, the present disclosure is not limited to this. The processing liquid supply device 2 may include the configuration of the processing liquid supply device 2 according to any one of the second to seventh embodiments, and may further include a processing liquid controller 21 capable of functioning as part of the controller 9 according to the embodiment.

### 10. Correspondences Between Constituent Elements in Claims and Parts in Preferred Embodiments

In the following paragraphs, non-limiting examples of correspondences between various elements recited in the claims below and those described above with respect to various preferred embodiments of the present disclosure are explained. As each of various elements recited in the claims, various other elements having configurations or functions described in the claims can be also used.

In the above-mentioned embodiment, the chamber 4 is an example of a chamber, the processing liquid supply device 2 is an example of a processing liquid supply device, the controller 9 and the processing liquid controller 21 are examples of a controller, the first temperature adjuster 12 is an example of a first temperature adjuster, the second temperature adjuster 13 is an example of a second temperature adjuster, the malfunction detectors 12s, 13s and the controller 9 are examples of a malfunction determiner, and the substrate processing apparatus 1 is an example of a substrate processing apparatus.

Further, the supply pipe p12 is an example of a first flow path and a supply flow path, the bypass pipe p14 is an example of a second flow path, the valve v01 is an example of a first valve, the valve v02 is an example of a second valve, the substrate processing section 3A is an example of a first tower, the substrate processing section 3B is an example of a second tower, the storage tank 10 is an example of a storage tank, and the circulation pipe p13 is an example of a circulation flow path and a first circulation flow path.

Further, the circulation pipe p15 is an example of a second circulation flow path, the plurality of chamber pipes p21 are an example of a plurality of first chamber flow paths, the plurality of chamber pipes p22 are an example of a plurality of second chamber flow paths, the flow-rate adjustment device 15 is an example of a flow-rate adjustment device, the liquid level sensor LS is an example of a liquid level detector, the liquid replenishing device 5 is an example of a liquid replenishing device, the lower limit level L1 is an example of a first liquid level height and a lower limit height, and the malfunction lower limit level L3 is an example of a second liquid level height.

### 11. Overview of Embodiments

(Item 1) A substrate processing apparatus according to item 1 includes a plurality of chambers in which a plurality of substrates are respectively processed using a processing liquid, a processing liquid supply device that supplies the processing liquid to the plurality of chambers, and a controller that controls the plurality of chambers and the processing liquid supply device, wherein the processing liquid supply device includes a first temperature adjuster and a second temperature adjuster that adjust a temperature of the processing liquid to be supplied to the plurality of chambers, and a malfunction determiner that is configured to determine whether the first temperature adjuster is malfunctioning and determine whether the second temperature adjuster is malfunctioning, and the controller, in a case in which the malfunction determiner determines that neither the first temperature adjuster nor the second temperature adjuster is malfunctioning, sets a first number equal to or smaller than a count of the plurality of chambers as a count of chambers to which the processing liquid is allowed to be simultaneously supplied from the processing liquid supply device, and in a case in which the malfunction determiner determines that one of the first temperature adjuster and the second temperature adjuster is malfunctioning and determines that another one of the first temperature adjuster and the second temperature adjuster is not malfunctioning, sets a second number smaller than the first number as the count of chambers to which the processing liquid is allowed to be simultaneously supplied from the processing liquid supply device.

In the substrate processing apparatus, whether the first temperature adjuster and the second temperature adjuster are malfunctioning is determined. In a case in which neither the first temperature adjuster nor the second temperature adjuster is malfunctioning, the first number is set as the number of chambers to which the processing liquid can be simultaneously supplied. Therefore, by appropriately defining the first number, it is possible to process the plurality of substrates with high efficiency using the temperature-adjusted processing liquid.

In a case in which one of the first temperature adjuster and the second temperature adjuster is malfunctioning and the other one of the first temperature adjuster and the second temperature adjuster is not malfunctioning, the second number smaller than the first number is set as the number of chambers to which the processing liquid can be simultaneously supplied. Thus, the supply flow rate of the processing liquid to the plurality of chambers is reduced as compared with a case in which the first number is set. Therefore, it is possible to maintain the work state of at least part of the plurality of chambers without causing a substrate processing defect at least for a certain period of time. As a result, it is possible to reduce the possibility that the work of the processing liquid supply device and the work in all of the plurality of chambers are stopped at an unintended point in time.

(Item 2) The substrate processing apparatus according to item 1, wherein the processing liquid supply device may further include a first flow path that guides the processing liquid to the plurality of chambers, and the first temperature adjuster and the second temperature adjuster may be arranged in series on the first flow path, and may adjust a temperature of the processing liquid flowing through the first flow path.

In this case, even in a case in which one of the first temperature adjuster and the second temperature adjuster is malfunctioning, when the other one of the first temperature adjuster and the second temperature adjuster is working normally, it is possible to continue adjusting the temperature of the processing liquid. Therefore, by appropriately restricting the number of chambers to which the processing liquid can be simultaneously supplied, it is possible to maintain the work state of the substrate processing apparatus without causing a substrate processing defect at least for a certain period of time.

(Item 3) The substrate processing apparatus according to item 1, wherein the processing liquid supply device may further include a first flow path that guides the processing liquid to the plurality of chambers, a second flow path that is connected to the first flow path to bypass one portion of the first flow path, a first valve provided in the one portion of the first flow path, and a second valve provided in the second flow path, the first temperature adjuster and the second temperature adjuster may be respectively provided in the one portion of the first flow path and the second flow path to be arranged in parallel, and the controller, in a case in which the malfunction determiner determines that the first temperature adjuster is malfunctioning and the second temperature adjuster is not malfunctioning, may put the first valve in a close state and put the second valve in an open state, and in a case in which the malfunction determiner determines that the first temperature adjuster is not malfunctioning and determines that the second temperature adjuster is malfunctioning, may put the first valve in an open state and put the second valve in a close state.

In this case, even in a case in which one of the first temperature adjuster and the second temperature adjuster is malfunctioning, when the other one of the first temperature adjuster and the second temperature adjuster is working normally, it is possible to continue adjusting the temperature of the processing liquid. Therefore, by appropriately restricting the number of chambers to which the processing liquid can be simultaneously supplied, it is possible to maintain the work state of the substrate processing apparatus without causing a substrate processing defect at least for a certain period of time.

Further, with the above-mentioned configuration, in a case in which the first temperature adjuster is malfunctioning and the second temperature adjuster is not malfunctioning, a flow of the processing liquid through part of the first flow path is blocked. Thus, the processing liquid flows through the second flow path so as to bypass part of the first flow path. At this time, the temperature of the processing liquid is adjusted by the second temperature adjuster.

Further, in a case in which the first temperature adjuster is not malfunctioning and the second temperature adjuster is malfunctioning, a flow of the processing liquid through part of the first flow path is blocked. Thus, the processing liquid flows through a portion of the first flow path. At this time, the temperature of the processing liquid is adjusted by the first temperature adjuster.

As a result, the processing liquid the temperature of which is not adjusted is not supplied to the chamber. Therefore, it reduces the possibility that the temperature of the processing liquid supplied to the chamber becomes unstable.

In a case in which neither the first temperature adjuster nor the second temperature adjuster is malfunctioning, the first valve and the second valve may be in the open state. Thus, a pressure loss generated in each liquid flow path can be reduced as compared with a case in which the first temperature adjuster and the second temperature adjuster are arranged in series.

(Item 4) The substrate processing apparatus according to item 1, wherein the plurality of chambers may include four or more chambers, the substrate processing apparatus may include a first tower including a structure in which two or more chambers out of the plurality of chambers are stacked, and a second tower including a structure in which other two or more chambers out of the plurality of chambers are stacked, the processing liquid supply device may include a storage tank that stores the processing liquid, a supply flow path in which the first temperature adjuster and the second temperature adjuster are provided and which extends from the storage tank, a first circulation flow path that puts a portion of the processing liquid back to the storage tank, with the portion of the processing liquid flowing downstream of the first temperature adjuster and the second temperature adjuster of the supply flow path, a plurality of first chamber flow paths that guide the processing liquid flowing through the first circulation flow path to the two or more chambers provided in the first tower, a second circulation flow path that puts another portion of the processing liquid back to the storage tank, with the another portion of the processing liquid flowing downstream of the first temperature adjuster and the second temperature adjuster of the supply flow path, and a plurality of second chamber flow paths that guide the processing liquid flowing through the second circulation flow path to the two or more chambers provided in the second tower, and regardless of a determination result of the malfunction determiner, the controller may control the processing liquid supply device to cause the processing liquid to flow through the first circulation flow path and the second circulation flow path.

In this case, even in a case in which the number of chambers to which the processing liquid can be simultaneously supplied is reduced, the processing liquid always flows through each of the first circulation flow path and the second circulation flow path. This suppresses a change in temperature of the processing liquid in the first circulation flow path and the second circulation flow path due to the stay of the processing liquid. This further suppresses generation of precipitates due to a change in temperature of the processing liquid. Therefore, it is possible to suppress degradation of temperature quality and degradation of the flow state of the processing liquid in the first circulation flow path and the second circulation flow path.

(Item 5) The substrate processing apparatus according to item 1, wherein the processing liquid supply device may further include a storage tank that stores the processing liquid, a supply flow path in which the first temperature adjuster and the second temperature adjuster are provided and which extends from the storage tank, a circulation flow path that puts at least one portion of the processing liquid back to the storage tank, with the at least one portion of the processing liquid flowing downstream of the first temperature adjuster and the second temperature adjuster of the supply flow path, and a flow-rate adjustment device that is provided in the supply flow path and adjusts a flow rate of the processing liquid flowing from the storage tank to the supply flow path, and the controller, in a case in which the malfunction determiner determines that neither the first temperature adjuster nor the second temperature adjuster is malfunctioning, may control the flow-rate adjustment device to adjust a flow rate of the processing liquid flowing from the storage tank to the supply flow path to a first flow rate, and in a case in which the malfunction determiner determines that one of the first temperature adjuster and the second temperature adjuster is malfunctioning and determines that another one of the first temperature adjuster and the second temperature adjuster is not malfunctioning, may control the flow-rate adjustment device to adjust a flow rate of the processing liquid flowing from the storage tank to the supply flow path to a second flow rate lower than the first flow rate.

With the above-mentioned configuration, the processing liquid circulates through the storage tank, the supply pipe and the circulation flow path. In a case in which neither the first temperature adjuster nor the second temperature adjuster is malfunctioning, the temperature of the circulating processing liquid is adjusted by the first temperature adjuster and the second temperature adjuster. However, when one of the first temperature adjuster and the second temperature adjuster is malfunctioning, it degrades efficiency of adjusting the temperature of the processing liquid flowing through the supply flow path. Therefore, it is likely to be difficult to maintain the temperature of the circulating processing liquid by using only the other temperature adjuster.

With the above-mentioned configuration, when one of the first temperature adjuster and the second temperature adjuster is malfunctioning, the flow rate of the processing liquid flowing from the storage tank to the supply flow path is reduced as compared with a case in which neither the first temperature adjuster nor the second temperature adjuster is malfunctioning. This facilitates maintenance of the temperature of the processing liquid circulating through the supply flow path and the circulation flow path.

(Item 6) The substrate processing apparatus according to item 1, wherein the processing liquid supply device may further include a storage tank that stores the processing liquid, a supply flow path in which the first temperature adjuster and the second temperature adjuster are provided and which extends from the storage tank, a circulation flow path that puts at least one portion of the processing liquid back to the storage tank, with the at least one portion of the processing liquid flowing downstream of the first temperature adjuster and the second temperature adjuster of the supply flow path, and a liquid level detector that detects a liquid level height of the processing liquid stored in the storage tank, and a liquid replenishing device that replenishes the storage tank with the processing liquid, and the controller, in a case in which the malfunction determiner determines that neither the first temperature adjuster nor the second temperature adjuster is malfunctioning, and a liquid level height detected by the liquid level detector is lowered to a first liquid level height, may control the liquid replenishing device to replenish the storage tank with the processing liquid until a prescribed amount of the processing liquid is stored in the storage tank, and in a case in which the malfunction determiner determines that one of the first temperature adjuster and the second temperature adjuster is malfunctioning and determines that another one of the first temperature adjuster and the second temperature adjuster is not malfunctioning, and a liquid level height detected by the liquid level detector is lowered to a second liquid level height higher than the first liquid level height, may control the liquid replenishing device to replenish the storage tank with the processing liquid until the prescribed amount of the processing liquid is stored in the storage tank.

With the above-mentioned configuration, the processing liquid circulates through the storage tank, the supply pipe and the circulation flow path. In a case in which neither the first temperature adjuster nor the second temperature adjuster is malfunctioning, the temperature of the circulating processing liquid is adjusted by the first temperature adjuster and the second temperature adjuster. When part of the circulating processing liquid is supplied to the plurality of chambers, the processing liquid in the storage tank is reduced. As such, because the liquid level of the processing liquid in the storage tank is lowered to the first liquid level height, the storage tank is replenished with a new processing liquid.

The temperature of the new processing liquid is normally not adjusted. Therefore, the temperature of the processing liquid in the storage tank temporarily changes. In order to supply the processing liquid having an appropriate temperature to the plurality of chambers regardless of a change in temperature of the processing liquid in the storage tank, the first temperature adjuster and the second temperature adjuster are required to have the temperature adjusting capacity equal to or higher than a certain level.

However, when one of the first temperature adjuster and the second temperature adjuster is malfunctioning, it degrades efficiency of adjusting the temperature of the processing liquid flowing through the supply flow path. That is, the temperature adjustment capacity equal to or higher than a certain level is not realized. Therefore, depending on a temperature change amount of the processing liquid in the storage tank, it may be difficult to appropriately adjust the temperature of the processing liquid using only a temperature adjuster that is not malfunctioning.

With the above-mentioned configuration, when the first temperature adjuster or the second temperature adjuster is malfunctioning, the liquid level of the processing liquid in the storage tank is lowered to the second liquid level height higher than the first liquid level height. Thus, the storage tank is replenished with the new processing liquid. In this case, as compared with a case in which neither the first temperature adjuster nor the second temperature adjuster is malfunctioning, an amount of the processing liquid with which the storage tank is replenished at one time is reduced. This reduces the temperature change amount of the processing liquid in the storage tank due to the replenishment with the processing liquid. As a result, it facilitates maintenance of the temperature of the processing liquid circulating through the supply flow path and the circulation flow path.

(Item 7) The substrate processing apparatus according to item 1, wherein the processing liquid supply device may further include a storage tank that stores the processing liquid, a supply flow path in which the first temperature adjuster and the second temperature adjuster are provided and which extends from the storage tank, a circulation flow path that puts at least one portion of the processing liquid back to the storage tank, with the at least one portion of the processing liquid flowing downstream of the first temperature adjuster and the second temperature adjuster of the supply flow path, a liquid level detector that detects a liquid level height of the processing liquid stored in the storage tank, and a liquid replenishing device that replenishes the storage tank with the processing liquid, and the controller, in a case in which the malfunction determiner determines that neither the first temperature adjuster nor the second temperature adjuster is malfunctioning, and a liquid level height detected by the liquid level detector is lowered to a predetermined lower limit height, may control the liquid replenishing device to replenish the storage tank with the processing liquid at a first replenishment rate until a prescribed amount of the processing liquid is stored in the storage tank, and in a case in which the malfunction determiner determines that one of the first temperature adjuster and the second temperature adjuster is malfunctioning and determines that another one of the first temperature adjuster and the second temperature adjuster is not malfunctioning, and a liquid level height detected by the liquid level detector is lowered to the lower limit level, may control the liquid replenishing device to replenish the storage tank with the processing liquid at a second replenishment flow rate lower than the first replenishment flow rate until the prescribed amount of the processing liquid is stored in the storage tank.

With the above-mentioned configuration, the processing liquid circulates through the storage tank, the supply pipe and the circulation flow path. In a case in which neither the first temperature adjuster nor the second temperature adjuster is malfunctioning, the temperature of the circulating processing liquid is adjusted by the first temperature adjuster and the second temperature adjuster. When part of the circulating processing liquid is supplied to the plurality of chambers, the processing liquid in the storage tank is reduced. As such, because the liquid level of the processing liquid in the storage tank is lowered to the lower limit height, the storage tank is replenished with a new processing liquid.

The temperature of the new processing liquid is normally not adjusted. Therefore, the temperature of the processing liquid in the storage tank temporarily changes. In order to supply the processing liquid having an appropriate temperature to the plurality of chambers regardless of a change in temperature of the processing liquid in the storage tank, the first temperature adjuster and the second temperature adjuster are required to have the temperature adjusting capacity equal to or higher than a certain level.

However, when one of the first temperature adjuster and the second temperature adjuster is malfunctioning, it degrades efficiency of adjusting the temperature of the processing liquid flowing through the supply flow path. That is, the temperature adjustment capacity equal to or higher than a certain level is not realized. Therefore, depending on a temperature change amount of the processing liquid in the storage tank, it may be difficult to appropriately adjust the temperature of the processing liquid using only a temperature adjuster that is not malfunctioning.

With the above-mentioned configuration, when the first temperature adjuster or the second temperature adjuster is malfunctioning, the replenishment flow rate of the new processing liquid with which the storage tank is replenished and which is supplied from the liquid replenishing device is reduced as compared with a case in which neither the first temperature adjuster nor the second temperature adjuster is malfunctioning. In this case, as compared with a case in which neither the first temperature adjuster nor the second temperature adjuster is malfunctioning, an amount of the processing liquid with which the storage tank is replenished per unit time is reduced. This reduces the temperature change amount of the processing liquid in the storage tank per unit time due to the replenishment with the processing liquid. As a result, it facilitates maintenance of the temperature of the processing liquid circulating through the supply flow path and the circulation flow path.

(Item 8) The substrate processing apparatus according to item 1, may further include a storage that stores temperature adjuster information and schedule information, with the temperature adjuster information representing temperature adjusting capacity of the first temperature adjuster and the second temperature adjuster, and with the schedule information representing contents of a process scheduled to be executed in the plurality of chambers and a count of substrates scheduled to be processed, wherein the processing liquid supply device may further include a storage tank that stores the processing liquid, a supply flow path in which the first temperature adjuster and the second temperature adjuster are provided and which extends from the storage tank, a circulation flow path that puts at least one portion of the processing liquid back to the storage tank, with the at least one portion of the processing liquid flowing downstream of the first temperature adjuster and the second temperature adjuster of the supply flow path, and a liquid replenishing device that replenishes the storage tank with the processing liquid, and the controller, in a case in which the malfunction determiner determines that one of the first temperature adjuster and the second temperature adjuster is malfunctioning and determines that another one of the first temperature adjuster and the second temperature adjuster is not malfunctioning, may acquire a physical quantity relating to a state of the processing liquid flowing from the storage tank through the supply flow path and the circulation flow path as circulation information, may acquire a physical quantity relating to a state of the processing liquid with which the storage tank is replenished and which is supplied from the liquid replenishing device as replenishment information, based on the temperature adjuster information, the circulation information and the replenishment information, may estimate, as a consumable amount, a maximum amount of the processing liquid supplied to at least one of the plurality of chambers while maintaining a temperature of the processing liquid flowing through the circulation flow path in a predetermined allowable range for a predetermined prescribed period, and may calculate the second number based on the estimated consumable amount and the schedule information.

In this case, in a case in which one of the first temperature adjuster and the second temperature adjuster is malfunctioning, the consumable amount is estimated based on the temperature adjuster information, the circulation information and the replenishment information. The second number is appropriately calculated based on the estimated consumable amount and the schedule information. As a result, degradation of substrate processing efficiency is alleviated.

(Item 9) The substrate processing apparatus according to any one of items 1 to 8, wherein the controller, in a case in which the malfunction determiner determines that the first temperature adjuster and the second temperature adjuster are malfunctioning, may stop work in the plurality of chambers and work of the processing liquid supply device.

In this case, the substrates are prevented from being continuously inappropriately processed. This suppresses wasteful consumption of the processing liquid and the substrates.

(Item 10) The substrate processing apparatus according to any one of items 1 to 9, wherein the processing liquid supply device may further include a temperature detector that detects a temperature of the processing liquid, with the processing liquid having a temperature adjusted by at least one of the first temperature adjuster and the second temperature adjuster and being supplied to at least one of the plurality of chambers, and the controller, in a case in which a temperature of the processing liquid detected by the temperature detector is not in a predetermined allowable range, may stop work in the plurality of chambers and work of the processing liquid supply device.

In this case, the substrates are prevented from being continuously inappropriately processed. This suppresses wasteful consumption of the processing liquid and the substrates.

(Item 11) A processing liquid supply device according to another aspect of the present disclosure that supplies a processing liquid to a plurality of chambers, with the plurality of chambers respectively executing a process using the processing liquid on a plurality of substrates, includes a first temperature adjuster and a second temperature adjuster that adjust a temperature of the processing liquid to be supplied to the plurality of chambers, a malfunction determiner configured to determine whether the first temperature adjuster is malfunctioning and configured to determine whether the second temperature adjuster is malfunctioning, and a controller, in a case in which the malfunction determiner determines that neither the first temperature adjuster nor the second temperature adjuster is malfunctioning, outputs an instruction signal for setting a first number equal to or smaller than a count of the plurality of chambers as a count of chambers in which work is allowed to be simultaneously performed, and in a case in which the malfunction determiner determines that one of the first temperature adjuster and the second temperature adjuster is malfunctioning and determines that another one of the first temperature adjuster and the second temperature adjuster is not malfunctioning, outputs an instruction signal for setting a second number smaller than the first number as the count of chambers to which the processing liquid is allowed to be simultaneously supplied.

In the processing liquid supply device, whether the first temperature adjuster and the second temperature adjuster are malfunctioning is determined. In a case in which neither the first temperature adjuster nor the second temperature adjuster is malfunctioning, an instruction signal for setting the first number as the number of chambers in which work can be simultaneously performed is output. Therefore, by appropriately defining the first number, it is possible to process the plurality of substrates with high efficiency using the temperature-adjusted processing liquid.

In a case in which one of the first temperature adjuster and the second temperature adjuster is malfunctioning and the other one of the first temperature adjuster and the second temperature adjuster is not malfunctioning, an instruction signal for setting the second number that is smaller than the first number is output as the number of chambers in which work can be simultaneously performed. Thus, the flow rate of the processing liquid supplied to the plurality of chambers is reduced as compared with a case in which the first number is set. Therefore, it is possible to maintain the work state of at least part of the plurality of chambers without causing a substrate processing defect at least for a certain period of time. As a result, it is possible to reduce the possibility that the work in all of the plurality of chambers is stopped at an unintended point in time.

(Item 12) A substrate processing method according to item 12 includes supplying a processing liquid to a plurality of chambers that respectively execute a process using the processing liquid on a plurality of substrates, and controlling the plurality of chambers, wherein the supplying a processing liquid to a plurality of chambers includes adjusting, using a first temperature adjuster and a second temperature adjuster, a temperature of the processing liquid to be supplied to the plurality of chambers, determining whether the first temperature adjuster is malfunctioning, and determining whether the second temperature adjuster is malfunctioning, and the controlling the plurality of chambers includes, in a case in which it is determined that neither the first temperature adjuster nor the second temperature adjuster is malfunctioning, setting a first number equal to or smaller than a count of the plurality of chambers as a count of chambers to which the processing liquid is allowed to be simultaneously supplied, and in a case in which it is determined that one of the first temperature adjuster and the second temperature adjuster is malfunctioning, and it is determined that another one of the first temperature adjuster and the second temperature adjuster is not malfunctioning, setting a second number smaller than the first number as the count of chambers to which the processing liquid is allowed to be simultaneously supplied.

With the substrate processing method, whether the first temperature adjuster and the second temperature adjuster are malfunctioning is determined. In a case in which neither the first temperature adjuster nor the second temperature adjuster is malfunctioning, the first number is set as the number of chambers to which the processing liquid can be simultaneously supplied. Therefore, by appropriately defining the first number, it is possible to process the plurality of substrates with high efficiency using the temperature-adjusted processing liquid.

In a case in which one of the first temperature adjuster and the second temperature adjuster is malfunctioning and the other one of the first temperature adjuster and the second temperature adjuster is not malfunctioning, the second number smaller than the first number is set as the number of chambers to which the processing liquid can be simultaneously supplied. Thus, the flow rate of the processing liquid supplied to the plurality of chambers is reduced as compared with a case in which the first number is set. Therefore, it is possible to maintain the work state of at least part of the plurality of chambers without causing a substrate processing defect at least for a certain period of time. As a result, it is possible to reduce the possibility that the work of the processing liquid supply device and the work in all of the plurality of chambers are stopped at an unintended point in time.

(Item 13) A processing liquid supply method according to item 13 of supplying a processing liquid to a plurality of chambers in which a plurality of substrates are respectively processed using a processing liquid, includes adjusting, using a first temperature adjuster and a second temperature adjuster, a temperature of the processing liquid to be supplied to the plurality of chambers, determining whether the first temperature adjuster is malfunctioning, determining whether the second temperature adjuster is malfunctioning, in a case in which it is determined that neither the first temperature adjuster nor the second temperature adjuster is malfunctioning, outputting an instruction signal for setting a first number equal to or smaller than a count of the plurality of chambers as a count of chambers in which work is allowed to be simultaneously performed, and in a case in which it is determined that one of the first temperature adjuster and the second temperature adjuster is malfunctioning, and it is determined that another one of the first temperature adjuster and the second temperature adjuster is not malfunctioning, outputting an instruction signal for setting a second number smaller than the first number as the count of chambers in which work is allowed to be simultaneously performed.

With the processing liquid supply method, whether the first temperature adjuster and the second temperature adjuster are malfunctioning is determined. In a case in which neither the first temperature adjuster nor the second temperature adjuster is malfunctioning, an instruction signal for setting the first number as the number of chambers in which work can be simultaneously performed is output. Therefore, by appropriately defining the first number, it is possible to process the plurality of substrates with high efficiency using the temperature-adjusted processing liquid.

In a case in which one of the first temperature adjuster and the second temperature adjuster is malfunctioning and the other one of the first temperature adjuster and the second temperature adjuster is not malfunctioning, an instruction signal for setting the second number that is smaller than the first number is output as the number of chambers in which work can be simultaneously performed. Thus, the flow rate of the processing liquid supplied to the plurality of chambers is reduced as compared with a case in which the first number is set. Therefore, it is possible to maintain the work state of at least part of the plurality of chambers without causing a substrate processing defect at least for a certain period of time. As a result, it is possible to reduce the possibility that the work in all of the plurality of chambers is stopped at an unintended point in time.

While preferred embodiments of the present disclosure have been described above, it is to be understood that variations and modifications will be apparent to those skilled in the art without departing the scope and spirit of the present disclosure. The scope of the present disclosure, therefore, is to be determined solely by the following claims.

We claim:

1. A substrate processing apparatus comprising:
a plurality of chambers in which a plurality of substrates are respectively processed using a processing liquid;
a processing liquid supply device that supplies the processing liquid to the plurality of chambers; and
a controller that controls the plurality of chambers and the processing liquid supply device, wherein
the processing liquid supply device includes
a first temperature adjuster and a second temperature adjuster that adjust a temperature of the processing liquid to be supplied to the plurality of chambers, and
a malfunction determiner that is configured to determine whether the first temperature adjuster is malfunctioning and determine whether the second temperature adjuster is malfunctioning, and
the controller,
in a case in which the malfunction determiner determines that neither the first temperature adjuster nor the second temperature adjuster is malfunctioning, sets a first number equal to or smaller than a count of the plurality of chambers as a count of chambers to which the processing liquid is allowed to be simultaneously supplied from the processing liquid supply device, and
in a case in which the malfunction determiner determines that one of the first temperature adjuster and the second temperature adjuster is malfunctioning and determines that another one of the first temperature adjuster and the second temperature adjuster is not malfunctioning, sets a second number smaller than the first number as the count of chambers to which the processing liquid is allowed to be simultaneously supplied from the processing liquid supply device.

2. The substrate processing apparatus according to claim 1, wherein
the processing liquid supply device further includes a first flow path that guides the processing liquid to the plurality of chambers, and
the first temperature adjuster and the second temperature adjuster are arranged in series on the first flow path, and adjusts a temperature of the processing liquid flowing through the first flow path.

3. The substrate processing apparatus according to claim 1, wherein
the processing liquid supply device further includes
a first flow path that guides the processing liquid to the plurality of chambers,
a second flow path that is connected to the first flow path to bypass one portion of the first flow path,
a first valve provided in the one portion of the first flow path, and
a second valve provided in the second flow path,
the first temperature adjuster and the second temperature adjuster are respectively provided in the one portion of the first flow path and the second flow path to be arranged in parallel, and
the controller,
in a case in which the malfunction determiner determines that the first temperature adjuster is malfunctioning and the second temperature adjuster is not malfunctioning, puts the first valve in a close state and puts the second valve in an open state, and
in a case in which the malfunction determiner determines that the first temperature adjuster is not malfunctioning and determines that the second temperature adjuster is malfunctioning, puts the first valve in an open state and puts the second valve in a close state.

4. The substrate processing apparatus according to claim 1, wherein
the plurality of chambers include four or more chambers,
the substrate processing apparatus includes
a first tower including a structure in which two or more chambers out of the plurality of chambers are stacked, and
a second tower including a structure in which other two or more chambers out of the plurality of chambers are stacked,
the processing liquid supply device includes
a storage tank that stores the processing liquid,
a supply flow path in which the first temperature adjuster and the second temperature adjuster are provided and which extends from the storage tank,
a first circulation flow path that puts a portion of the processing liquid back to the storage tank, with the portion of the processing liquid flowing downstream of the first temperature adjuster and the second temperature adjuster of the supply flow path,
a plurality of first chamber flow paths that guide the processing liquid flowing through the first circulation flow path to the two or more chambers provided in the first tower,
a second circulation flow path that puts another portion of the processing liquid back to the storage tank, with the another portion of the processing liquid flowing downstream of the first temperature adjuster and the second temperature adjuster of the supply flow path, and
a plurality of second chamber flow paths that guide the processing liquid flowing through the second circulation flow path to the two or more chambers provided in the second tower, and
regardless of a determination result of the malfunction determiner, the controller controls the processing liquid supply device to cause the processing liquid to flow through the first circulation flow path and the second circulation flow path.

5. The substrate processing apparatus according to claim 1, wherein
the processing liquid supply device further includes
a storage tank that stores the processing liquid,
a supply flow path in which the first temperature adjuster and the second temperature adjuster are provided and which extends from the storage tank,
a circulation flow path that puts at least one portion of the processing liquid back to the storage tank, with the at least one portion of the processing liquid flowing downstream of the first temperature adjuster and the second temperature adjuster of the supply flow path, and
a flow-rate adjustment device that is provided in the supply flow path and adjusts a flow rate of the processing liquid flowing from the storage tank to the supply flow path, and
the controller,
in a case in which the malfunction determiner determines that neither the first temperature adjuster nor the second temperature adjuster is malfunctioning, controls the flow-rate adjustment device to adjust a flow rate of the processing liquid flowing from the storage tank to the supply flow path to a first flow rate, and
in a case in which the malfunction determiner determines that one of the first temperature adjuster and the second temperature adjuster is malfunctioning and determines that another one of the first temperature adjuster and the second temperature adjuster is not malfunctioning, controls the flow-rate adjustment device to adjust a flow rate of the processing liquid flowing from the storage tank to the supply flow path to a second flow rate lower than the first flow rate.

6. The substrate processing apparatus according to claim 1, wherein
the processing liquid supply device further includes
a storage tank that stores the processing liquid,
a supply flow path in which the first temperature adjuster and the second temperature adjuster are provided and which extends from the storage tank,
a circulation flow path that puts at least one portion of the processing liquid back to the storage tank, with the at least one portion of the processing liquid flowing downstream of the first temperature adjuster and the second temperature adjuster of the supply flow path, and
a liquid level detector that detects a liquid level height of the processing liquid stored in the storage tank, and
a liquid replenishing device that replenishes the storage tank with the processing liquid, and
the controller,
in a case in which the malfunction determiner determines that neither the first temperature adjuster nor the second temperature adjuster is malfunctioning, and a liquid level height detected by the liquid level detector is lowered to a first liquid level height, controls the liquid replenishing device to replenish the storage tank with the processing liquid until a prescribed amount of the processing liquid is stored in the storage tank, and
in a case in which the malfunction determiner determines that one of the first temperature adjuster and the second temperature adjuster is malfunctioning and determines that another one of the first temperature adjuster and the second temperature adjuster is not malfunctioning, and a liquid level height detected by the liquid level detector is lowered to a second liquid level height higher than the first liquid level height, controls the liquid replenishing device to replenish the storage tank with the processing liquid until the prescribed amount of the processing liquid is stored in the storage tank.

7. The substrate processing apparatus according to claim 1, wherein
the processing liquid supply device further includes
a storage tank that stores the processing liquid,
a supply flow path in which the first temperature adjuster and the second temperature adjuster are provided and which extends from the storage tank,
a circulation flow path that puts at least one portion of the processing liquid back to the storage tank, with the at least one portion of the processing liquid flowing downstream of the first temperature adjuster and the second temperature adjuster of the supply flow path,
a liquid level detector that detects a liquid level height of the processing liquid stored in the storage tank, and
a liquid replenishing device that replenishes the storage tank with the processing liquid, and
the controller,
in a case in which the malfunction determiner determines that neither the first temperature adjuster nor the second temperature adjuster is malfunctioning, and a liquid level height detected by the liquid level detector is lowered to a predetermined lower limit height, controls the liquid replenishing device to replenish the storage tank with the processing liquid at a first replenishment flow rate until a prescribed amount of the processing liquid is stored in the storage tank, and
in a case in which the malfunction determiner determines that one of the first temperature adjuster and the second temperature adjuster is malfunctioning and determines that another one of the first temperature adjuster and the second temperature adjuster is not malfunctioning, and a liquid level height detected by the liquid level detector is lowered to the lower limit level, controls the liquid replenishing device to replenish the storage tank with the processing liquid at a second replenishment flow rate lower than the first replenishment flow rate until the prescribed amount of the processing liquid is stored in the storage tank.

8. The substrate processing apparatus according to claim 1, further comprising a storage that stores temperature adjuster information and schedule information, the temperature adjuster information representing temperature adjusting capacity of the first temperature adjuster and the second temperature adjuster, the schedule information representing contents of a process scheduled to be executed in the plurality of chambers and a count of substrates scheduled to be processed, wherein
the processing liquid supply device further includes
a storage tank that stores the processing liquid,
a supply flow path in which the first temperature adjuster and the second temperature adjuster are provided and which extends from the storage tank,
a circulation flow path that puts at least one portion of the processing liquid back to the storage tank, with the at least one portion of the processing liquid flowing downstream of the first temperature adjuster and the second temperature adjuster of the supply flow path, and
a liquid replenishing device that replenishes the storage tank with the processing liquid, and
the controller,
in a case in which the malfunction determiner determines that one of the first temperature adjuster and the second temperature adjuster is malfunctioning and determines that another one of the first temperature adjuster and the second temperature adjuster is not malfunctioning,
acquires a physical quantity relating to a state of the processing liquid flowing from the storage tank through the supply flow path and the circulation flow path as circulation information,
acquires a physical quantity relating to a state of the processing liquid with which the storage tank is replenished and which is supplied from the liquid replenishing device as replenishment information,
based on the temperature adjuster information, the circulation information and the replenishment information, estimates, as a consumable amount, a maximum amount of the processing liquid supplied to at least one of the plurality of chambers while maintaining a temperature of the processing liquid flowing through the circulation flow path in a predetermined allowable range for a predetermined prescribed period, and
calculates the second number based on the estimated consumable amount and the schedule information.

9. The substrate processing apparatus according to claim 1, wherein
the controller, in a case in which the malfunction determiner determines that the first temperature adjuster and the second temperature adjuster are malfunctioning, stops work in the plurality of chambers and work of the processing liquid supply device.

10. The substrate processing apparatus according to claim 1, wherein
the processing liquid supply device further includes
a temperature detector that detects a temperature of the processing liquid, with the processing liquid having a temperature adjusted by at least one of the first temperature adjuster and the second temperature adjuster and being supplied to at least one of the plurality of chambers, and
the controller, in a case in which a temperature of the processing liquid detected by the temperature detector is not in a predetermined allowable range, stops work in the plurality of chambers and work of the processing liquid supply device.

11. A processing liquid supply device that supplies a processing liquid to a plurality of chambers, the plurality of chambers respectively executing a process using the processing liquid on a plurality of substrates, comprising:
a first temperature adjuster and a second temperature adjuster that adjust a temperature of the processing liquid to be supplied to the plurality of chambers;
a malfunction determiner configured to determine whether the first temperature adjuster is malfunctioning and configured to determine whether the second temperature adjuster is malfunctioning; and
a controller, in a case in which the malfunction determiner determines that neither the first temperature adjuster nor the second temperature adjuster is malfunctioning, outputs an instruction signal for setting a first number equal to or smaller than a count of the plurality of chambers as a count of chambers in which work is allowed to be simultaneously performed, and in a case in which the malfunction determiner determines that one of the first temperature adjuster and the second temperature adjuster is malfunctioning and determines that another one of the first temperature adjuster and the second temperature adjuster is not malfunctioning, outputs an instruction signal for setting a second number smaller than the first number as the count of chambers to which the processing liquid is allowed to be simultaneously supplied.

12. A substrate processing method including:
supplying a processing liquid to a plurality of chambers that respectively execute a process using the processing liquid on a plurality of substrates; and
controlling the plurality of chambers, wherein
the supplying a processing liquid to a plurality of chambers includes
adjusting, using a first temperature adjuster and a second temperature adjuster, a temperature of the processing liquid to be supplied to the plurality of chambers,
determining whether the first temperature adjuster is malfunctioning, and
determining whether the second temperature adjuster is malfunctioning, and
the controlling the plurality of chambers includes,
in a case in which it is determined that neither the first temperature adjuster nor the second temperature adjuster is malfunctioning, setting a first number equal to or smaller than a count of the plurality of chambers as a count of chambers to which the processing liquid is allowed to be simultaneously supplied, and
in a case in which it is determined that one of the first temperature adjuster and the second temperature adjuster is malfunctioning, and it is determined that another one of the first temperature adjuster and the second temperature adjuster is not malfunctioning, setting a second number smaller than the first number as the count of chambers to which the processing liquid is allowed to be simultaneously supplied.

13. A processing liquid supply method of supplying a processing liquid to a plurality of chambers in which a plurality of substrates are respectively processed using a processing liquid, including:
adjusting, using a first temperature adjuster and a second temperature adjuster, a temperature of the processing liquid to be supplied to the plurality of chambers;
determining whether the first temperature adjuster is malfunctioning;
determining whether the second temperature adjuster is malfunctioning;
in a case in which it is determined that neither the first temperature adjuster nor the second temperature adjuster is malfunctioning, outputting an instruction signal for setting a first number equal to or smaller than a count of the plurality of chambers as a count of chambers in which work is allowed to be simultaneously performed; and
in a case in which it is determined that one of the first temperature adjuster and the second temperature adjuster is malfunctioning, and it is determined that another one of the first temperature adjuster and the second temperature adjuster is not malfunctioning, outputting an instruction signal for setting a second number smaller than the first number as the count of chambers in which work is allowed to be simultaneously performed.
